(19) United States
(12) Patent Application Publication
(10) Pub. No.: US 2026/0147067 A1
(43) Pub. Date: May 28, 2026

(54) MAGNETIC FIELD DETECTION APPARATUS

(71) Applicant: SUZHOU NOVOSENSE MICROELECTRONICS CO., LTD., Suzhou (CN)

(72) Inventors: Fute YUAN, Suzhou (CN); Long ZHANG, Suzhou (CN)

(73) Assignee: SUZHOU NOVOSENSE MICROELECTRONICS CO., LTD., Suzhou (CN)

(21) Appl. No.: 19/178,492

(22) Filed: Apr. 14, 2025

(30) Foreign Application Priority Data
Nov. 7, 2024 (CN) 202411585831.X

(51) Int. Cl. G01R 33/00; G01R 33/02; G01R 33/09

(52) U.S. Cl. CPC G01R 33/0017; G01R 33/0206; G01R 33/09

(57) ABSTRACT

The present application discloses a magnetic field detection apparatus, comprising: a detection module configured to generate a magnetic field detection signal; and a calibration module configured to generate a reference signal. The reference signal is used to calibrate the magnetic field detection signal, and the reference signal is independent of a uniform ambient magnetic field. When a value of the reference signal satisfies a first relationship with a first preset value, the magnetic field detection signal is amplified; or, when a value of the reference signal satisfies a second relationship with a second preset value, the magnetic field detection signal is attenuated. The magnetic field detection apparatus provided by the present application enables calibration of the magnetic field detection signal at a numerical level to eliminate linear errors, thereby avoiding issues such as detection range contraction caused by power consumption constraints.

### TECHNICAL FIELD

The present application relates to the field of testing and measurement technology, particularly to a magnetic field detection apparatus.

### BACKGROUND

Magnetic sensors are used to detect magnetic fields and have a wide range of application scenarios. In consumer electronics, their applications include triaxial magnetometers for measuring geomagnetism, magnetic displacement meters for measuring lens movements, and magnetic switches for detecting screen opening/closing. In industrial and transportation equipment, their applications encompass angle sensors, current sensors, etc.

To ensure measurement stability, magnetoresistive materials can be used to fabricate magnetic sensors. However, such magnetoresistive-based sensors rely on the properties of magnetic materials, thus exhibiting an inherent physical characteristic where the linearity error of the output curve increases with the strength of the measured magnetic field. Calibration devices can be employed to address this issue.

Existing techniques utilize two sensors to measure a target magnetic field and cross-reference measurement results to counteract the linearity error caused by increasing magnetic field strength. However, the magnetic field measurement process and error compensation calibration are mutually exclusive in these methods, requiring switching between measurement mode and calibration mode. This mode-switching interrupts normal detection processes, making them unsuitable for high-bandwidth application scenarios. Additionally, as the sensors need corresponding configurations, the power consumption of calibration processes and other electrical parameter settings must be adjusted according to on-site operating conditions, thereby limiting the detectable magnetic field range supported by the measurement system.

### SUMMARY

One of the objectives of the present application is to provide a magnetic field detection apparatus to address technical issues in the prior art, such as linear errors in magnetic field detection processes and the inability to meet high-bandwidth or wide detection range requirements.

To achieve one of the aforementioned inventive objectives, an embodiment of the present application provides a magnetic field detection apparatus, comprising: a detection module configured to generate a magnetic field detection signal; and a calibration module configured to generate a reference signal; the reference signal is configured to calibrate the magnetic field detection signal, and the reference signal is independent of a uniform ambient magnetic field; when a value of the reference signal satisfies a first relationship with a first preset value, the magnetic field detection signal is amplified; or, when a value of the reference signal satisfies a second relationship with a second preset value, the magnetic field detection signal is attenuated.

Compared with the prior art, the magnetic field detection apparatus provided by the present application achieves the following advantages: By employing independent detection and calibration modules, it avoids bandwidth limitations caused by alternating detection and calibration steps. Adjusting the magnitude of a magnetic field detection signal at the detection module based on a value of a reference signal enables calibration at the numerical level to eliminate linear errors. By configuring the reference signal to be independent of uniform ambient magnetic fields, it prevents the reference signal or the calibration module generating it from being affected by ambient magnetic fields, thereby preserving the overall performance of the apparatus. Specifically, the configuration provided by the present application avoids detection range contraction caused by power consumption constraints.

### BRIEF DESCRIPTION OF THE DRAWINGS

FIG. 1 is a structural schematic diagram of a magnetic field detection apparatus according to an embodiment of the present application.

FIG. 2 is a structural schematic diagram of a magnetic field detection apparatus according to a first embodiment of the present application.

FIG. 3 is a structural schematic diagram of a magnetic field detection apparatus according to a second embodiment of the present application.

FIG. 4 is a structural schematic diagram of a magnetic field detection apparatus according to a third embodiment of the present application.

FIG. 5 is a structural schematic diagram of a magnetic field detection apparatus according to a fourth embodiment of the present application.

FIG. 6 is a structural schematic diagram of a magnetic field detection apparatus according to a fifth embodiment of the present application.

FIG. 7 is a structural schematic diagram of a magnetic field detection apparatus according to a sixth embodiment of the present application.

FIG. 8 is a structural schematic diagram of a calibration module according to an embodiment of the present application.

FIG. 9 is a structural schematic diagram of a calibration module according to a first example of the present application.

FIG. 10 is a structural schematic diagram of a detection unit according to a second example of the present application.

FIG. 11 is a structural schematic diagram of a detection unit according to a third example of the present application.

FIG. 12 is a partial structural schematic diagram of a detection unit according to a fourth example of the present application.

FIG. 13 is a structural schematic diagram of a detection unit according to a fourth example of the present application.

FIG. 14 is a partial structural schematic diagram of a detection unit according to a fifth example of the present application.

FIG. 15 is a structural schematic diagram of a detection unit according to a fifth example of the present application.

FIG. 16 is a structural schematic diagram of a detection unit according to a sixth example of the present application.

FIG. 17 is a partial structural schematic diagram of a detection unit according to a seventh example of the present application.

FIG. 18 is a structural schematic diagram of a detection unit according to a seventh example of the present application.

### DETAILED DESCRIPTION

The following detailed description of the present application will be provided with reference to specific implementations illustrated in accompanying drawings. However, these implementations do not limit the scope of the present application. Structural, methodological, or functional modifications made by a person of ordinary skill in the art based on these implementations shall fall within the scope of protection of the present application.

It should be noted that the term “comprise” or any of its variants is intended to cover non-exclusive inclusion, such that a process, method, article, or device comprising a list of elements not only includes those explicitly listed elements but also may include other elements not expressly stated or inherent to such process, method, article, or device. Furthermore, terms such as “first,” “second,” “third,” etc., are used solely for descriptive purposes and should not be interpreted as indicating or implying relative importance.

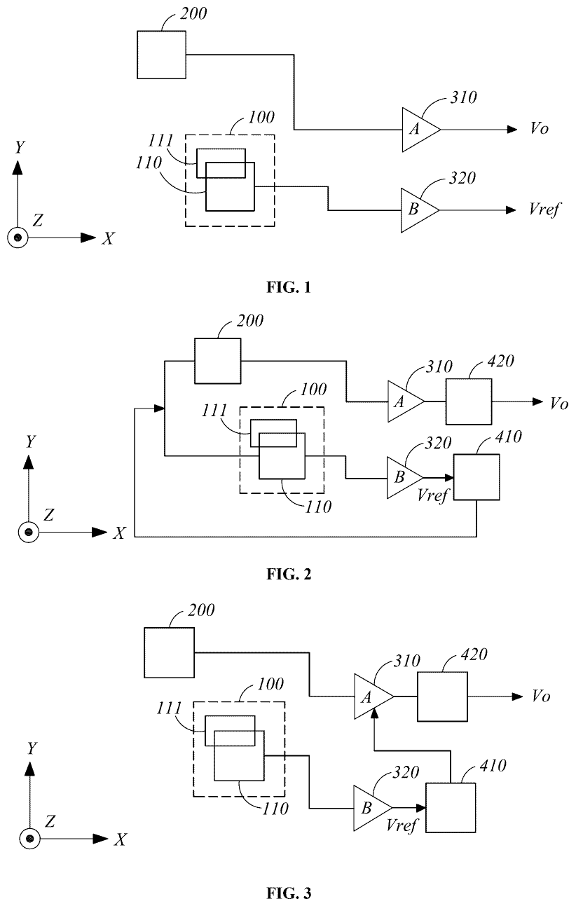

In an embodiment of the present application, a magnetic field detection apparatus is provided, as shown in FIG. 1.

The magnetic field detection apparatus is used for detecting magnetic field information.

The magnetic field detection apparatus comprises a detection module 200.

The detection module 200 is configured to generate a magnetic field detection signal Vo. The magnetic field detection apparatus may directly output the magnetic field detection signal Vo, or process the magnetic field detection signal Vo before outputting. The processing of the magnetic field detection signal Vo by the magnetic field detection apparatus may include operations, calibration, standardization, etc. In an embodiment, or in an operating state, the magnetic field detection apparatus may also directly output the magnetic field detection signal Vo.

The detection module 200 is configured to detect an ambient magnetic field.

The magnetic field detection apparatus comprises a calibration module 100.

The calibration module 100 is configured to generate a reference signal Vref. The reference signal Vref is configured to calibrate the magnetic field detection signal.

The calibration module 100 and the detection module 200 are separately arranged to form two signal paths, which can effectively prevent the calibration process from compressing the bandwidth of the magnetic field detection signal, enabling real-time sensitivity calibration under high-bandwidth signal output.

The method by which the reference signal Vref calibrates the magnetic field detection signal Vo may be used as a reference basis for adjusting the magnetic field detection signal Vo, participating in subsequent processing of the magnetic field detection signal Vo to generate a final output of the magnetic field detection apparatus, or determining a final output through operations such as superposition or subtraction with the magnetic field detection signal Vo.

The reference signal Vref is used to adjust the strength of the magnetic field detection signal Vo. Thus, linear error elimination can be achieved by adjusting the magnitude of the magnetic field detection signal Vo.

In an embodiment, the reference signal Vref is used to amplify the magnetic field detection signal Vo.

When the value of the reference signal Vref satisfies a first relationship with a first preset value, the magnetic field detection signal Vo is amplified. Thus, the current state of the magnetic field detection signal Vo can be determined through numerical judgment, and the numerical distribution range of the magnetic field detection signal Vo can be changed through amplification processing, thereby correcting the magnetic field detection sensitivity of the detection module 200.

In an embodiment, the reference signal Vref is used to attenuate the magnetic field detection signal Vo.

When the value of the reference signal Vref satisfies a second relationship with a second preset value, the magnetic field detection signal Vo is attenuated. Thus, the current state of the magnetic field detection signal Vo can be determined through numerical judgment, and the numerical distribution range of the magnetic field detection signal Vo can be changed through attenuation processing, thereby correcting the magnetic field detection sensitivity of the detection module 200.

The reference signal Vref is independent of a uniform ambient magnetic field. Thus, the reference signal Vref is independent of the ambient magnetic field, eliminating the need to adjust electrical parameters (e.g., current flowing through the calibration module 100) at the calibration module 100 based on the strength of the ambient magnetic field, avoiding issues such as excessive power consumption and poor power supply capability leading to compressed magnetic field detection range, and enabling more accurate magnetic field detection sensitivity calibration.

In an embodiment, the first preset value equals the second preset value. In the embodiment, when the reference signal Vref satisfies the first relationship with the first preset value or does not satisfy the second relationship with the second preset value, the magnetic field detection signal Vo is amplified; when the reference signal Vref does not satisfy the first relationship with the first preset value or satisfies the second relationship with the second preset value, the magnetic field detection signal Vo is attenuated.

In an embodiment, the first relationship includes: the value of the reference signal Vref is less than the first preset value. In the embodiment, when the value of the reference signal Vref is less than the first preset value, the magnetic field detection signal Vo is amplified.

When the reference signal Vref is less than the first preset value, it indicates that the quality of the magnetic field detection signal Vo is below a set requirement; the first preset value can be set accordingly.

In an embodiment, the second relationship includes: the value of the reference signal Vref is greater than the second preset value. In the embodiment, when the value of the reference signal Vref is greater than the second preset value, the magnetic field detection signal Vo is amplified.

When the reference signal Vref is greater than the second preset value, it indicates that the quality of the magnetic field detection signal Vo is below a set requirement; the second preset value can be set accordingly.

In an embodiment, the magnetic field detection apparatus further comprises a first amplifier 310.

An input terminal of the first amplifier 310 is coupled to the detection module 200, and an output of the first amplifier 310 is used to generate a magnetic field detection signal Vo. By amplifying the output of the detection module 200, the magnetic field detection signal Vo can be processed for computation or other subsequent processing.

In an embodiment, the magnetic field detection apparatus further comprises a second amplifier 320.

An input terminal of the second amplifier 320 is coupled to the calibration module 100, and an output of the second amplifier 320 is used to generate a reference signal Vref. By amplifying the output of the calibration module 100, the reference signal Vref can be processed for computation or other subsequent processing.

The strength of the magnetic field detection signal Vo can be controlled by controlling a driving current input to the detection module 200.

The strength of the magnetic field detection signal Vo can be controlled by controlling a driving voltage input to the detection module 200.

In an embodiment, the amplification of the magnetic field detection signal Vo can be achieved by increasing a driving current input to the detection module 200.

In an embodiment, the amplification of the magnetic field detection signal Vo can be achieved by increasing a driving voltage input to the detection module 200.

In an embodiment, the attenuation of the magnetic field detection signal Vo can be achieved by decreasing a driving current input to the detection module 200.

In an embodiment, the attenuation of the magnetic field detection signal Vo can be achieved by decreasing a driving voltage input to the detection module 200.

Thus, by increasing or decreasing the driving current or driving voltage, the output of the magnetic field detection signal Vo is affected, achieving the effect of linear error calibration.

In an embodiment, the process of controlling the driving voltage input to the detection module 200 or controlling the driving current input to the detection module 200 can be implemented by setting up a processing module in the magnetic field detection apparatus.

As shown in FIG. 2, in a first embodiment provided by the present application, the magnetic field detection apparatus further comprises a first processing module 410.

The first processing module 410 is configured to control a driving current or driving voltage.

The first processing module 410 may take the form of an electronic control unit or integrated circuit. The first processing module 410 may specifically include a driving circuit, an amplification circuit, a filtering circuit, an analog-to-digital converter, a microcontroller or a digital signal processor, and a communication interface, etc.

The first processing module 410 can control the driving voltage by outputting variable voltage through a digital-to-analog converter. The first processing module 410 can control the driving voltage and driving current through generating pulse width modulation signals by controlling duty cycle and frequency; the first processing module 410 can control the driving voltage or driving current by using variable gain amplifiers through controlling gain; the first processing module 410 can implement control by forming a feedback loop.

In an embodiment, an output terminal of the first processing module 410 is coupled to an input terminal of the detection module 200, configured to output a calibration value. The calibration value is used to control the driving current or to control the driving voltage.

In a specific embodiment, an output terminal of the first processing module 410 is also coupled to an input terminal of the calibration module 100, configured to output a calibration value. By synchronously adjusting the driving current of the calibration module 100 and the detection module 200, or synchronously adjusting the driving voltage of the calibration module 100 and the detection module 200, linear error calibration operation can be achieved stably and quickly.

When the driving current or driving voltage increases, causing the reference signal Vref and the magnetic field detection signal Vo to increase accordingly, the first preset value or second preset value used for comparison with the value of the reference signal Vref to determine error conditions can also increase accordingly to match, facilitating dynamic feedback adjustment. Conversely, when the driving current or driving voltage decreases, causing the reference signal Vref and the magnetic field detection signal Vo to decrease accordingly, the first preset value or second preset value used for comparison with the value of the reference signal Vref to determine error conditions can decrease accordingly to match.

In an embodiment, the first processing module 410 is configured to output a first calibration value when the value of the reference signal Vref satisfies a first relationship with a first preset value.

In an embodiment, when the detection module 200 receives a first calibration value, the magnetic field detection signal Vo is amplified.

In a specific embodiment, the first calibration value can be an electrical signal, such as a digital signal, an analog signal, or a mechanical signal such as an action signal.

In a specific embodiment, the first processing module 410 is configured to output a first calibration value when the value of the reference signal Vref is less than a first preset value.

In an embodiment, the first processing module 410 is configured to output a second calibration value when the value of the reference signal Vref satisfies a second relationship with a second preset value.

In an embodiment, when the detection module 200 receives a second calibration value, the magnetic field detection signal Vo is attenuated.

In a specific embodiment, the second calibration value can be an electrical signal, such as a digital signal, an analog signal, or a mechanical signal such as an action signal.

In a specific embodiment, the first processing module 410 is configured to output a second calibration value when the value of the reference signal Vref is greater than a second preset value.

In a specific embodiment, the first calibration value is configured to increase a driving current.

In a specific embodiment, the first calibration value is configured to increase a driving voltage.

In a specific embodiment, the second calibration value is configured to decrease a driving current.

In a specific embodiment, the second calibration value is configured to decrease a driving voltage.

In an embodiment, an input terminal of the first processing module 410 is coupled to an output terminal of the calibration module 100. The input terminal of the first processing module 410 is configured to receive a reference signal Vref output from the calibration module 100.

In an embodiment, the magnetic field detection apparatus further includes a second amplifier 320. An input terminal of the second amplifier 320 is coupled to an output terminal of the calibration module 100, and an output terminal of the second amplifier 320 is coupled to an input terminal of the first processing module 410. The second amplifier 320 generates the reference signal Vref after amplifying the output from the calibration module 100.

In an embodiment, the magnetic field detection apparatus further comprises a second processing module 420.

In an embodiment, an output terminal of the second processing module 420 is configured to generate the magnetic field detection signal Vo based on the output of the detection module 200.

In a specific embodiment, the second processing module 420 includes a sampling circuit that samples the signal at an output terminal of the second processing module 420 according to a preset sampling frequency.

In an embodiment, an input terminal of the second processing module 420 is coupled to an output terminal of the detection module 200.

In a specific embodiment, an input terminal of the second processing module 420 is electrically connected to an output terminal of the detection module 200. In the embodiment, the coupling is specifically an electrical connection.

In a specific embodiment, the magnetic field detection apparatus further comprises a first amplifier 310. An input terminal of the first amplifier 310 is coupled to an output terminal of the detection module 200, and an output terminal of the first amplifier 310 is coupled to an input terminal of the second processing module 420. The second processing module 420 generates the magnetic field detection signal Vo based on an amplified output from the first amplifier 310. In the embodiment, the coupling is specifically an indirect connection established through the first amplifier 310.

The strength of the magnetic field detection signal Vo can be controlled by controlling the amplification factor for generating the magnetic field detection signal Vo.

In an embodiment, the amplification of the magnetic field detection signal Vo can be achieved by increasing an amplification factor for generating the magnetic field detection signal Vo.

In an embodiment, the attenuation of the magnetic field detection signal Vo can be achieved by decreasing an amplification factor for generating the magnetic field detection signal Vo.

Thus, affecting the output of the magnetic field detection signal Vo achieves the effect of linear error calibration.

In an embodiment, the adjustment of the amplification factor for generating the magnetic field detection signal Vo can be implemented by setting up a processing module in the magnetic field detection apparatus.

As shown in FIG. 3, in a second embodiment provided by the present application, the magnetic field detection apparatus further comprises a first processing module 410.

The first processing module 410 is configured to control the amplification factor of the magnetic field detection signal of the magnetic field detection apparatus.

In an embodiment, an output terminal of the first processing module 410 is coupled to a control terminal of the detection module 200, configured to output a calibration value. The calibration value is used to control the amplification factor of the magnetic field detection signal Vo.

When the amplification factor increases, causing the reference signal Vref and the magnetic field detection signal Vo to increase accordingly, the first preset value or second preset value used for comparison with the value of the reference signal Vref to determine error conditions can also increase accordingly to match, facilitating dynamic feedback adjustment. Conversely, when the amplification factor decreases, causing the reference signal Vref and the magnetic field detection signal Vo to decrease accordingly, the first preset value or second preset value used for comparison with the value of the reference signal Vref to determine error conditions can decrease accordingly to match.

In an embodiment, the first processing module 410 is configured to output a third calibration value when the value of the reference signal Vref satisfies a first relationship with a first preset value.

In an embodiment, when the detection module 200 receives a third calibration value, the magnetic field detection signal Vo is amplified.

In an embodiment, when the first amplifier 310 receives a third calibration value, the magnetic field detection signal Vo is amplified.

In a specific embodiment, the third calibration value can be an electrical signal, such as a digital signal, an analog signal, or a mechanical signal such as an action signal.

In a specific embodiment, the first processing module 410 is configured to output a third calibration value when the value of the reference signal Vref is less than a first preset value.

In an embodiment, the first processing module 410 is configured to output a fourth calibration value when the value of the reference signal Vref satisfies a second relationship with a second preset value.

In an embodiment, when the detection module 200 receives a fourth calibration value, the magnetic field detection signal Vo is attenuated.

In an embodiment, when the first amplifier 310 receives a fourth calibration value, the magnetic field detection signal Vo is attenuated.

In a specific embodiment, the fourth calibration value can be an electrical signal, such as a digital signal, an analog signal, or a mechanical signal such as an action signal.

In a specific embodiment, the first processing module 410 is configured to output a fourth calibration value when the value of the reference signal Vref is greater than a second preset value.

In a specific embodiment, the third calibration value is configured to increase an amplification factor.

In a specific embodiment, the fourth calibration value is configured to decrease an amplification factor.

In an embodiment, an input terminal of the first processing module 410 is coupled to an output terminal of the calibration module 100. The input terminal of the first processing module 410 is configured to receive the reference signal Vref output from the calibration module 100.

In an embodiment, the magnetic field detection apparatus further comprises a second amplifier 320. An input terminal of the second amplifier 320 is coupled to an output terminal of the calibration module 100, and an output terminal of the second amplifier 320 is coupled to an input terminal of the first processing module 410. The second amplifier 320 generates the reference signal Vref after amplifying the output from the calibration module 100.

In an embodiment, the adjustment of the amplification factor for generating the magnetic field detection signal Vo can be implemented by setting up an amplifier in the magnetic field detection apparatus.

In a second embodiment provided by the present application, the magnetic field detection apparatus further comprises a first amplifier 310.

An input terminal of the first amplifier 310 is coupled to an output terminal of the detection module 200. An output of the first amplifier 310 is used to generate the magnetic field detection signal Vo.

The first amplifier 310 is configured to receive a calibration value and control its own amplification factor for the output of the detection module 200. The first amplifier 310 specifically receives an external control signal through a control terminal of the first amplifier 310; the external control signal includes at least a calibration value.

In an embodiment, the magnetic field detection apparatus comprises a first processing module 410, with an output terminal of the first processing module 410 coupled to a control terminal of the first amplifier 310, configured to output a calibration value to control the amplification factor of the first amplifier 310. In some embodiments, the first processing module 410 is configured to output the third calibration value. In some embodiments, the first processing module 410 is configured to output the fourth calibration value.

In an embodiment, the magnetic field detection apparatus further comprises a second processing module 420.

In an embodiment, an output terminal of the second processing module 420 is configured to generate the magnetic field detection signal Vo based on the output of the detection module 200.

An output terminal of the first amplifier 310 is coupled to an input terminal of the second processing module 420. The second processing module 420 generates the magnetic field detection signal Vo based on an amplified output from the first amplifier 310.

The strength of the magnetic field detection signal Vo can be controlled by controlling the operational gain for generating the magnetic field detection signal Vo.

In an embodiment, the amplification of the magnetic field detection signal Vo can be achieved by increasing an operational gain for generating the magnetic field detection signal Vo.

In an embodiment, the attenuation of the magnetic field detection signal Vo can be achieved by decreasing an operational gain for generating the magnetic field detection signal Vo.

Thus, affecting the output of the magnetic field detection signal Vo achieves the effect of linear error calibration.

In an embodiment, the adjustment of the operational gain for generating the magnetic field detection signal Vo can be implemented by setting up a processing module in the magnetic field detection apparatus.

As shown in FIG. 3, in a second embodiment provided by the present application, the magnetic field detection apparatus further comprises a second processing module 420.

The second processing module 420 performs computational processing on the input signal to the second processing module 420 based on a set operational gain.

In an embodiment, an output terminal of the second processing module 420 is configured to output a processed magnetic field detection signal Vo.

In an embodiment, an input terminal of the second processing module 420 is coupled to an output terminal of the detection module 200, configured to perform computational processing on the output of the detection module 200.

The second processing module 420 is configured to receive a calibration value and control its own operational gain for the output of the detection module 200 (or, in some embodiments, for the output of the first amplifier 310). The second processing module 420 specifically receives an external control signal through a control terminal of the second processing module 420; the external control signal includes at least a calibration value.

The magnetic field detection apparatus further comprises a first processing module 410.

The first processing module 410 is configured to control the operational gain of the magnetic field detection signal of the magnetic field detection apparatus.

In an embodiment, an output terminal of the first processing module 410 is coupled to a control terminal of the detection module 200, configured to output a calibration value.

In an embodiment, an output terminal of the first processing module 410 is coupled to a control terminal of the second processing module 420, configured to output a calibration value. The calibration value is used to control the operational gain of the magnetic field detection signal Vo.

When the operational gain increases, causing the reference signal Vref and the magnetic field detection signal Vo to increase accordingly, the first preset value or second preset value used for comparison with the value of the reference signal Vref to determine error conditions can also increase accordingly to match, facilitating dynamic feedback adjustment. Conversely, when the operational gain decreases, causing the reference signal Vref and the magnetic field detection signal Vo to decrease accordingly, the first preset value or second preset value used for comparison with the value of the reference signal Vref to determine error conditions can decrease accordingly to match.

In an embodiment, the first processing module 410 is configured to output a fifth calibration value when the value of the reference signal Vref satisfies a first relationship with a first preset value.

In an embodiment, when the detection module 200 receives a fifth calibration value, the magnetic field detection signal Vo is amplified.

In an embodiment, when the second processing module 420 receives a fifth calibration value, the magnetic field detection signal Vo is amplified.

In a specific embodiment, the fifth calibration value can be an electrical signal, such as a digital signal, an analog signal, or a mechanical signal such as an action signal.

In a specific embodiment, the first processing module 410 is configured to output a fifth calibration value when the value of the reference signal Vref is less than a first preset value.

In an embodiment, the first processing module 410 is configured to output a sixth calibration value when the value of the reference signal Vref satisfies a second relationship with a second preset value.

In an embodiment, when the detection module 200 receives a sixth calibration value, the magnetic field detection signal Vo is attenuated.

In an embodiment, when the first amplifier 310 receives a sixth calibration value, the magnetic field detection signal Vo is attenuated.

In a specific embodiment, the sixth calibration value can be an electrical signal, such as a digital signal, an analog signal, or a mechanical signal such as an action signal.

In a specific embodiment, the first processing module 410 is configured to output a sixth calibration value when the value of the reference signal Vref is greater than a second preset value.

In a specific embodiment, the fifth calibration value is configured to increase an operational gain.

In a specific embodiment, the sixth calibration value is configured to decrease an operational gain.

In an embodiment, an input terminal of the first processing module 410 is coupled to an output terminal of the calibration module 100. The input terminal of the first processing module 410 is configured to receive the reference signal Vref output from the calibration module 100.

In an embodiment, the magnetic field detection apparatus further comprises a second amplifier 320. An input terminal of the second amplifier 320 is coupled to an output terminal of the calibration module 100, and an output terminal of the second amplifier 320 is coupled to an input terminal of the first processing module 410. The second amplifier 320 generates the reference signal Vref after amplifying the output from the calibration module 100.

In a third embodiment provided by the present application, the magnetic field detection apparatus further comprises a first amplifier 310.

An input terminal of the first amplifier 310 is coupled to an output terminal of the detection module 200. An output of the first amplifier 310 is used to generate the magnetic field detection signal Vo.

The present application does not limit the number of detection modules 200, calibration modules 100, and related amplifiers and processing modules in the magnetic field detection apparatus.

For example, in some embodiments, multiple detection modules 200 can be set up in the magnetic field detection apparatus; multiple detection modules 200 can be set up in different regions, different locations, or in the same region, same location. In some embodiments, multiple calibration modules 100 can be set up in the magnetic field detection apparatus.

As shown in FIGS. 5 to 7, in some embodiments provided by the present application, the magnetic field detection apparatus comprises a first detection module 210; the detection module 200 comprises the first detection module 210.

In an embodiment, the first detection module 210 is configured to generate a magnetic field detection signal; specifically, the first detection module 210 is configured to detect an ambient magnetic field and generate a corresponding magnetic field detection signal.

In a specific embodiment, the first detection module 210 can be functionally or structurally configured as the detection module 200 in any embodiment of the present application.

In an embodiment, a first detection module 210 is disposed in a first region. The first detection module 210 is able to detect the condition of the ambient magnetic field in the first region.

The magnetic field detection apparatus comprises a second detection module 220; the detection module 200 comprises the second detection module 220.

In an embodiment, the second detection module 220 is configured to generate a magnetic field detection signal; specifically, the second detection module 220 is configured to detect an ambient magnetic field and generate a corresponding magnetic field detection signal.

In a specific embodiment, the second detection module 220 can be functionally or structurally configured as the detection module 200 in any embodiment of the present application.

In an embodiment, a second detection module 220 is disposed in a second region. The second region is different from the first region. The second detection module 220 is able to detect the condition of the ambient magnetic field in the second region.

The first detection module 210 can be configured to generate a first detection signal. The second detection module 220 can be configured to generate a second detection signal.

The magnetic field detection signal can be determined based on the first detection signal and the second detection signal, enabling comprehensive determination of a current state and value of the ambient magnetic field.

For example, when the magnetic field detection signal is determined based on a difference between the first detection signal and the second detection signal, the magnetic field detection signal can be used to characterize a magnetic field gradient between different regions and determine whether the ambient magnetic field is uniform. When the magnetic field detection signal is determined based on a superposition of the first detection signal and the second detection signal, the magnetic field detection signal can eliminate the gradient effects of non-uniform magnetic fields, obtaining a more accurate magnetic field condition.

As shown in FIG. 5, in a fourth embodiment provided by the present application, the magnetic field detection apparatus comprises a first detection module 210 disposed in a first region and a second detection module 220 disposed in a second region; the detection module 200 comprises the first detection module 210 and the second detection module 220. In an embodiment, the second region is different from the first region.

An output terminal of the second detection module 220 is coupled to an output terminal of the first detection module 210, configured to generate the magnetic field detection signal. Thus, a differential output can be formed through coupling the output terminals to characterize the difference in magnetic field strength between the first region and the second region.

In an embodiment, after coupling the output terminals of the first detection module 210 and the second detection module 220, they can directly serve as an output node to output the magnetic field detection signal Vo.

In an embodiment, the magnetic field detection apparatus further comprises a first amplifier 310; an output terminal of the first detection module 210 and an output terminal of the second detection module 220 are coupled to form a node, which is coupled to an input terminal of the first amplifier 310; the output terminal of the first amplifier 310 is configured to generate the magnetic field detection signal Vo.

In an embodiment, an output terminal of the calibration module 100 is directly defined as an output node of the magnetic field detection apparatus to output the reference signal Vref.

In an embodiment, the magnetic field detection apparatus further comprises a second amplifier 320; an output terminal of the calibration module 100 is coupled to an input terminal of the second amplifier 320; an output terminal of the second amplifier 320 is configured to generate the reference signal Vref.

As shown in FIG. 6, in a fifth embodiment provided by the present application, the magnetic field detection apparatus comprises a first detection module 210 disposed in a first region and a second detection module 220 disposed in a second region; the detection module 200 comprises a first detection module 210 and a second detection module 220. In an embodiment, the second region is different from the first region.

The magnetic field detection apparatus further comprises a first amplifier 310, with a first input terminal of the first amplifier 310 coupled to an output terminal of the first detection module 210 and a second input terminal of the first amplifier 310 coupled to an output terminal of the second detection module 220. Thus, subtraction can be performed through the first amplifier 310, achieving differential output based on a first detection signal output by the first detection module 210 and a second detection signal output by the second detection module 220.

In an embodiment, the first input terminal of the first amplifier 310 is a non-inverting input terminal of an amplifier, and the second input terminal of the first amplifier 310 is an inverting input terminal of an amplifier; in an embodiment, the first input terminal of the first amplifier 310 is an inverting input terminal of an amplifier, and the second input terminal of the first amplifier 310 is a non-inverting input terminal of an amplifier.

The output terminal of the first amplifier 310 is configured to generate the magnetic field detection signal Vo.

In an embodiment, an output terminal of the calibration module 100 is directly defined as an output node of the magnetic field detection apparatus to output the reference signal Vref.

In an embodiment, the magnetic field detection apparatus further comprises a second amplifier 320; an output terminal of the calibration module 100 is coupled to an input terminal of the second amplifier 320; an output terminal of the second amplifier 320 is configured to generate the reference signal Vref.

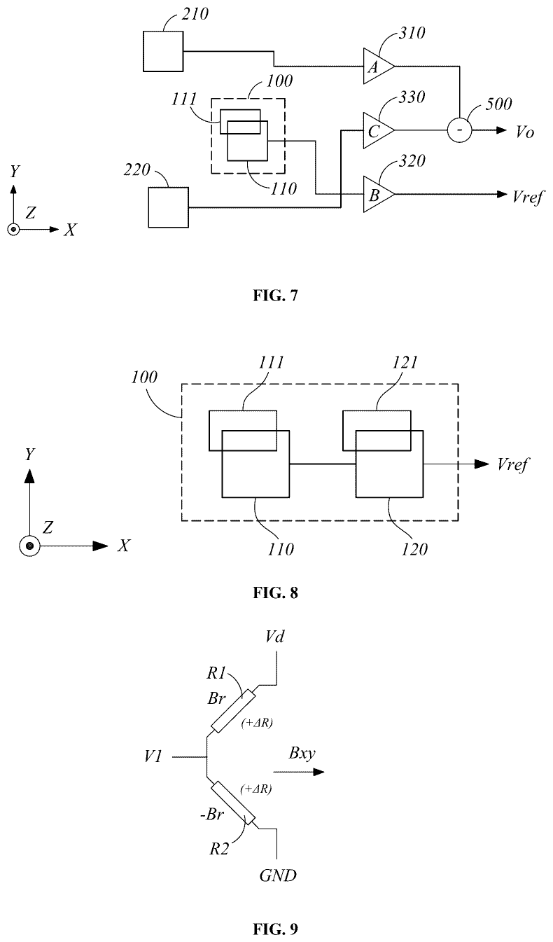

As shown in FIG. 7, in a sixth embodiment provided by the present application, the magnetic field detection apparatus comprises a first detection module 210 disposed in a first region and a second detection module 220 disposed in a second region; the detection module 200 comprises a first detection module 210 and a second detection module 220. In an embodiment, the second region is different from the first region.

The first detection module 210 is configured to generate a first detection signal. The second detection module 200 is configured to generate a second detection signal.

The magnetic field detection apparatus further comprises a subtractor 500, which is configured to generate the magnetic field detection signal Vo based on the first detection signal and the second detection signal. Thus, differential output of the two detection signals can be achieved through subtraction operation by the subtractor 500.

In an embodiment, a first input terminal of the subtractor 500 is coupled to the first detection module 210, a second input terminal of the subtractor 500 is coupled to the second detection module 220, and an output terminal of the subtractor 500 is configured to generate the magnetic field detection signal Vo.

In an embodiment, the magnetic field detection apparatus comprises a first amplifier 310. An input terminal of the first amplifier 310 is coupled to an output terminal of the first detection module 210, and an output terminal of the first amplifier 310 is coupled to a first input terminal of the subtractor 500.

In an embodiment, an output terminal of the calibration module 100 is directly defined as an output node of the magnetic field detection apparatus to output the reference signal Vref.

In an embodiment, the magnetic field detection apparatus further comprises a second amplifier 320; an output terminal of the calibration module 100 is coupled to an input terminal of the second amplifier 320; an output terminal of the second amplifier 320 is configured to generate the reference signal Vref.

In an embodiment, the magnetic field detection apparatus comprises a third amplifier 330. An input terminal of the third amplifier 330 is coupled to an output terminal of the second detection module 220, and an output terminal of the third amplifier 330 is coupled to a second input terminal of the subtractor 500.

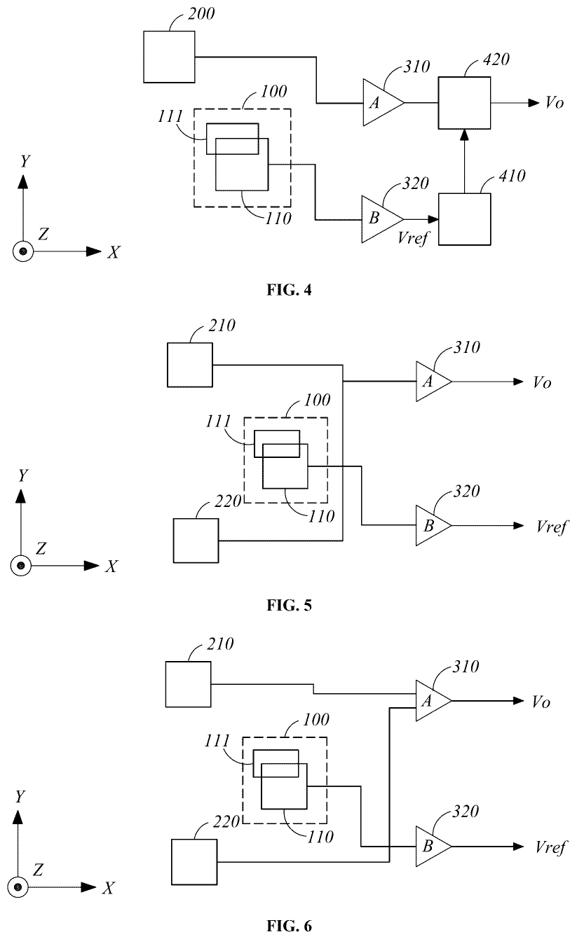

As shown in FIGS. 1 to 7, the first amplifier 310 can be set to have an amplification factor A; the second amplifier 320 can be set to have an amplification factor B. As shown in FIG. 7, the third amplifier 330 can be set to have an amplification factor C.

As shown in FIGS. 1 to 7, the calibration module 100 in any of the above technical solutions may comprise a first detection unit 110.

The first detection unit 110 can be used to detect magnetic fields. In an embodiment, the first detection unit 110 comprises a magnetoresistor. In an embodiment, the first detection unit 110 comprises a Hall element.

In an embodiment, the first detection unit 110 has a detection direction parallel to a plane where the first detection unit 110 is located. For example, the first detection unit 110 may have a detection direction along a first direction X or its opposite direction; for example, the first detection unit 110 may have a detection direction along a second direction Y or its opposite direction.

In an embodiment, the first detection unit 110 has a detection direction perpendicular to a plane where the first detection unit 110 is located. For example, the first detection unit 110 may have a detection direction along a third direction Z or its opposite direction (perpendicular to the paper plane inward).

The calibration module 100 comprises a first magnetic field generator 111.

The first magnetic field generator 111 is configured to apply a first magnetic field to the first detection unit 110. In an embodiment, the first magnetic field generator 111 includes a coil, magnet, or other structure configured to generate a local magnetic field. In a specific embodiment, the first magnetic field generator 111 is a coil, and during operation, current is applied to the first magnetic field generator 111 to generate the first magnetic field.

In an embodiment, the first magnetic field generator 111 is disposed close to the first detection unit 110.

In an embodiment, the first detection unit 110 is configured to produce electrical changes in response to a magnetic field component in a direction. The electrical changes may include resistance changes, current changes through the first detection unit 110, voltage changes across the first detection unit 110, or charge changes carried by the first detection unit 110. The first magnetic field generator 111 generates at least a component of the first magnetic field in that direction, causing the first detection unit 110 to produce the electrical changes.

In an embodiment, the first magnetic field is parallel to a detection direction of the first detection unit 110.

The first magnetic field can be a calibration magnetic field used to generate the reference signal Vref. The strength of the calibration magnetic field is characterized by a value of the reference signal Vref.

The calibration module 100 may comprise a set of detection units and magnetic field generators. The calibration module 100 only comprises the aforementioned first detection unit 110 and first magnetic field generator 111. The first magnetic field generator 111 applies the first magnetic field as a calibration magnetic field.

In other words, the magnetic field generator is configured to apply a calibration magnetic field to the detection unit. The direction of the calibration magnetic field is parallel to a detection direction of the detection unit.

The calibration module 100 can also comprise multiple sets of detection units and magnetic field generators. For example, as shown in FIG. 8, the calibration module 100 further comprises a second detection unit 120 and a second magnetic field generator 121.

The second detection unit 120 can be used to detect magnetic fields. In an embodiment, the second detection unit 120 comprises a magnetoresistor. In an embodiment, the second detection unit 120 comprises a Hall element.

In an embodiment, the second detection unit 120 has a detection direction parallel to a plane where the second detection unit 120 is located. For example, the second detection unit 120 may have a detection direction along a first direction X or its opposite direction; for example, the second detection unit 120 may have a detection direction along a second direction Y or its opposite direction.

In an embodiment, the second detection unit 120 has a detection direction perpendicular to the plane where the second detection unit 120 is located. For example, the second detection unit 120 may have a detection direction along a third direction Z or its opposite direction (perpendicular to the paper plane inward).

The calibration module 100 comprises a second magnetic field generator 121.

The second magnetic field generator 121 is configured to apply a second magnetic field to the second detection unit 120. In an embodiment, the second magnetic field generator 121 includes a coil, magnet, or other structure configured to generate a local magnetic field. In a specific embodiment, the second magnetic field generator 121 is a coil, and during operation, current is applied to the second magnetic field generator 121 to generate the second magnetic field.

In an embodiment, the second magnetic field generator 121 is disposed close to the second detection unit 120.

In an embodiment, the second detection unit 120 is configured to produce electrical changes in response to a magnetic field component in a direction. The electrical changes may include resistance changes, current changes through the second detection unit 120, voltage changes across the second detection unit 120, or charge changes carried by the second detection unit 120. The second magnetic field generator 121 generates at least a component of the second magnetic field in that direction, causing the second detection unit 120 to produce the electrical changes.

In an embodiment, the second magnetic field is parallel to a detection direction of the second detection unit 120.

In an embodiment, the first detection unit 110 is coupled to the second detection unit 120, configured to make the calibration module 100 produce no output in response to an ambient magnetic field.

The second detection unit 120 may be included in the detection unit, the second magnetic field generator 121 may be included in the magnetic field generator, and the second magnetic field may be included in the calibration magnetic field.

In an embodiment, the second magnetic field includes a magnetic field component that is opposite to a direction of the first magnetic field; or, the first magnetic field includes a magnetic field component that is opposite to a direction of the second magnetic field.

In an embodiment, the first magnetic field has a single magnetic field direction, the second magnetic field has a single magnetic field direction, and the direction of the first magnetic field is opposite to a direction of the second magnetic field.

In an embodiment, the strength of the first magnetic field equals the strength of the second magnetic field.

The second detection unit 120 has a preset position relationship with the first detection unit 110.

The preset position relationship may refer to a coupling relationship between the first detection unit 110 and the second detection unit 120. The coupling relationship can be used to characterize the relationship between signals at the first detection unit 110 and signals at the second detection unit 120, or to characterize the relationship between current/voltage at the first detection unit 110 and current/voltage at the second detection unit 120.

The preset position relationship includes: a relationship between the position of the first detection unit 110 relative to a power supply terminal and the position of the second detection unit 120 relative to the power supply terminal.

For example, in an embodiment shown in FIG. 9, the first detection unit 110 comprises a first magnetoresistor R1, which is located relatively closer to a power supply terminal Vd side; the second detection unit 120 comprises a second magnetoresistor R2, which is located relatively farther from the power supply terminal Vd side.

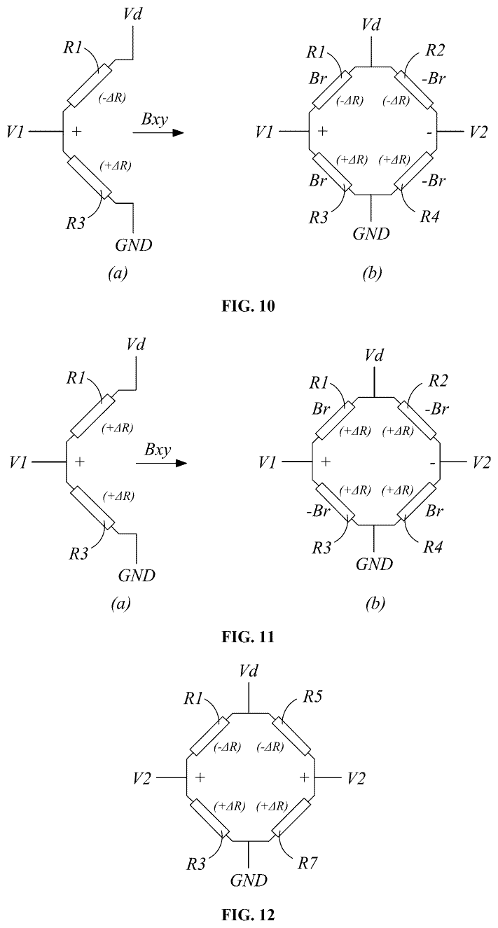

For example, in embodiments sn in FIGS. 10, 11, 13, 15, and 16, the first detection unit 110 comprises a first magnetoresistor R1, which is located relatively closer to a power supply terminal Vd side; the second detection unit 120 comprises a second magnetoresistor R2, which is located relatively closer to the power supply terminal Vd side.

For example, in an embodiment shown in FIG. 18, the first detection unit 110 comprises a first Hall element H1, with a first terminal e11 of the first Hall element H1 coupled to a power supply terminal Vd; the second detection unit 120 comprises a second Hall element H2, with a first terminal e21 of the second Hall element H2 coupled to the power supply terminal Vd.

The preset position relationship includes: a relationship between the position of the first detection unit 110 relative to a ground terminal and the position of the second detection unit 120 relative to the ground terminal.

For example, in the embodiment shown in FIG. 9, the first detection unit 110 comprises a first magnetoresistor R1, which is located relatively farther from a ground terminal GND side; the second detection unit 120 comprises a second magnetoresistor R2, which is located relatively closer to the ground terminal GND side.

For example, in embodiments shown in FIGS. 10, 11, 13, 15, and 16, the first detection unit 110 comprises a first magnetoresistor R1, which is located relatively farther from a ground terminal GND side; the second detection unit 120 comprises a second magnetoresistor R2, which is located relatively farther from the ground terminal GND side.

For example, in an embodiment shown in FIG. 18, the first detection unit 110 comprises a first Hall element H1, with a second terminal e12 of the first Hall element H1 coupled to a ground terminal GND; the second detection unit 120 comprises a second Hall element H2, with a second terminal e22 of the second Hall element H2 coupled to the ground terminal GND.

The calibration module is configured to generate a reference signal Vref. The reference signal Vref is independent of a uniform ambient magnetic field. Thus, the reference signal Vref is independent of the ambient magnetic field, eliminating the need to adjust current based on ambient magnetic field strength, avoiding issues such as excessive power consumption and poor power supply capability leading to compressed magnetic field detection range, and enabling more accurate magnetic field detection sensitivity calibration.

In a specific embodiment, the reference signal Vref is independent of non-uniform ambient magnetic fields.

In a specific embodiment, the reference signal Vref is only related to the first magnetic field and the second magnetic field.

In a specific embodiment, based on the position relationship between the first detection unit 110 and the second detection unit 120, by applying the first magnetic field to the first detection unit 110 and applying the second magnetic field containing a magnetic field component opposite to a direction of the first magnetic field to the second detection unit 120, the reference signal Vref is made independent of the uniform ambient magnetic field.

Thus, the calibration module can provide a reference signal independent of the ambient magnetic field, avoiding the impact of power consumption on magnetic field detection calibration process in the prior art, achieving accurate detection of magnetic fields over a wider range, and ensuring the elimination of linear error effects. Moreover, since the calibration module does not rely on the detection module used for detecting the magnetic field to be measured, it does not affect the operation of the detection module, which is more conducive to adapting to high-bandwidth application scenarios.

FIG. 9 shows a structure of the calibration module 100 in a first embodiment of the present application.

The calibration module 100 comprises a first magnetoresistor R1.

The calibration module 100 comprises a second magnetoresistor R2.

In an embodiment, a first terminal of the first magnetoresistor R1 is coupled to a power supply terminal Vd; a first terminal of the second magnetoresistor R2 is coupled to a second terminal of the first magnetoresistor R1; a second terminal of the second magnetoresistor R2 is coupled to a ground terminal GND.

In an embodiment, the calibration signal is related to a voltage value V1 at the second terminal of the first magnetoresistor R1.

In an embodiment, the calibration signal is related to a voltage value V1 at the first terminal of the second magnetoresistor R2.

In an embodiment, an output node is formed between the second terminal of the first magnetoresistor R1 and the first terminal of the second magnetoresistor R2, and the output node is used to output the calibration signal.

Thus, a calibration module can be constructed in a form of a half-bridge structure through coupled magnetoresistors to implement calibration of the magnetic field detection process.

Magnetoresistors can have positive magnetoresistance effect +ΔR or negative magnetoresistance effect −ΔR. When a magnetoresistor has a positive magnetoresistance effect +ΔR, its resistance value increases with increasing strength of the applied magnetic field and decreases with decreasing strength of the applied magnetic field. When a magnetoresistor has a negative magnetoresistance effect −ΔR, its resistance value increases with decreasing strength of the applied magnetic field and decreases with increasing strength of the applied magnetic field.

In an embodiment, the first magnetoresistor R1 has a positive magnetoresistance effect +ΔR, and the second magnetoresistor R2 has a positive magnetoresistance effect +ΔR.

In an embodiment, the first magnetoresistor R1 has a negative magnetoresistance effect −ΔR, and the second magnetoresistor R2 has a negative magnetoresistance effect −ΔR.

The calibration module 100 further comprises a first magnetic field generator 111.

The calibration module 100 further comprises a second magnetic field generator 121.

The first magnetic field generator 111 is configured to apply a first magnetic field to the first magnetoresistor R1.

The second magnetic field generator 121 is configured to apply a second magnetic field to the second magnetoresistor R2. The second magnetic field includes a magnetic field component opposite to a direction of the first magnetic field.

For example, when the first magnetic field generator 111 applies a first magnetic field Br to the first magnetoresistor R1, and the second magnetic field generator 121 applies a second magnetic field-Br to the second magnetoresistor R2, since the resistance changes of the first magnetoresistor R1 and the second magnetoresistor R2 in response to magnetic fields are in a same direction, the half-bridge structure formed by coupling produces no output for uniform ambient magnetic fields; and because the first magnetic field Br and second magnetic field-Br used to generate the calibration signal are in opposite directions, the half-bridge structure formed by coupling can produce a calibration signal with voltage value V1 that is independent of uniform ambient magnetic fields.

FIGS. 10 and 11 show the structures of the calibration module 100 in second and third embodiments of the present application.

The calibration module 100 comprises a first magnetoresistor R1.

The calibration module 100 comprises a second magnetoresistor R2.

The second magnetoresistor R2 has a preset position relationship with the first magnetoresistor.

In an embodiment, as shown in FIG. 10(b) and FIG. 11(c), the preset position relationship satisfies: a first terminal of the first magnetoresistor R1 is coupled to a power supply terminal Vd; a first terminal of the second magnetoresistor R2 is coupled to the power supply terminal Vd.

In an embodiment, the preset position relationship satisfies: a second terminal of the first magnetoresistor R1 is coupled to a ground terminal GND; a second terminal of the second magnetoresistor R2 is coupled to the ground terminal GND.

The second magnetoresistor R2 has a preset magnetoresistance effect relationship with the first magnetoresistor.

In an embodiment, the first magnetoresistor R1 has a positive magnetoresistance effect +ΔR, and the second magnetoresistor R2 has a positive magnetoresistance effect +ΔR.

In an embodiment, the first magnetoresistor R1 has a negative magnetoresistance effect −ΔR, and the second magnetoresistor R2 has a negative magnetoresistance effect −ΔR.

In a preferred embodiment, as shown in FIG. 10, a first terminal of the first magnetoresistor R1 is coupled to a power supply terminal Vd, a first terminal of the second magnetoresistor R2 is coupled to the power supply terminal Vd; and, the first magnetoresistor R1 has a positive magnetoresistance effect +ΔR, the second magnetoresistor R2 has a positive magnetoresistance effect +ΔR.

In a preferred embodiment, as shown in FIG. 11, a first terminal of the first magnetoresistor R1 is coupled to a power supply terminal Vd, a first terminal of the second magnetoresistor R2 is coupled to the power supply terminal Vd; and, the first magnetoresistor R1 has a negative magnetoresistance effect −ΔR, the second magnetoresistor R2 has a negative magnetoresistance effect −ΔR.

The calibration module 100 further comprises a first magnetic field generator 111.

The calibration module 100 further comprises a second magnetic field generator 121.

The first magnetic field generator 111 is configured to apply a first magnetic field to the first magnetoresistor R1.

The second magnetic field generator 121 is configured to apply a second magnetic field to the second magnetoresistor R2. The second magnetic field comprises a magnetic field component opposite to a direction of the first magnetic field.

Thus, by utilizing the magnetoresistance effect relationship of the two magnetoresistors and the corresponding applied calibration magnetic fields containing opposite magnetic field components, no output is produced for ambient magnetic fields through mutual comparison.

FIG. 10 shows a second embodiment provided by the present application.

As shown in FIG. 10(a), the calibration module 100 further comprises a third magnetoresistor R3.

A first terminal of the third magnetoresistor R3 is coupled to a second terminal of the first magnetoresistor R1, and a second terminal of the third magnetoresistor R3 is coupled to a ground terminal GND.

A first terminal of the first magnetoresistor R1 is coupled to a power supply terminal Vd.

Thus, forming a half-bridge structure magnetoresistor configuration.

In an embodiment, the calibration signal is related to a voltage value V1 at a second terminal of the first magnetoresistor R1.

In an embodiment, the calibration signal is related to a voltage value V1 at a first terminal of the third magnetoresistor R3.

In an embodiment, an output node is formed between a second terminal of the first magnetoresistor R1 and a first terminal of the third magnetoresistor R3, and an output node is used to generate the calibration signal.

The third magnetoresistor R3 has a preset magnetoresistance effect relationship with the first magnetoresistor R1.

In an embodiment, the first magnetoresistor R1 has a negative magnetoresistance effect −ΔR, and the third magnetoresistor R3 has a positive magnetoresistance effect +ΔR.

In an embodiment, the first magnetoresistor R1 has a positive magnetoresistance effect +ΔR, and the third magnetoresistor R3 has a negative magnetoresistance effect −ΔR.

In an embodiment, the first magnetic field generator 111 is configured to apply a third magnetic field to the third magnetoresistor R3. The third magnetic field includes a magnetic field component in a same direction as the first magnetic field. In a specific embodiment, the third magnetic field is the same as the first magnetic field.

As shown in FIG. 10, the calibration module 100 further comprises a fourth magnetoresistor R4.

A first terminal of the fourth magnetoresistor R4 is coupled to a second terminal of the second magnetoresistor R2, and a second terminal of the fourth magnetoresistor R4 is coupled to a ground terminal GND.

A first terminal of the second magnetoresistor R2 is coupled to a power supply terminal Vd.

Thus, a second detection unit 120 has a half-bridge structure magnetoresistor configuration.

In an embodiment, the calibration signal is related to a voltage value V2 at the second terminal of the second magnetoresistor R2.

In an embodiment, the calibration signal is related to a voltage value V2 at the first terminal of the fourth magnetoresistor R4.

In an embodiment, an output node is formed between a second terminal of the second magnetoresistor R2 and a first terminal of the fourth magnetoresistor R4, and the output node is used to generate the calibration signal.

The fourth magnetoresistor R4 has a preset magnetoresistance effect relationship with the second magnetoresistor R2.

In an embodiment, the second magnetoresistor R2 has a negative magnetoresistance effect −ΔR, and the fourth magnetoresistor R4 has a positive magnetoresistance effect +ΔR.

In an embodiment, the second magnetoresistor R2 has a positive magnetoresistance effect +ΔR, and the fourth magnetoresistor R4 has a negative magnetoresistance effect −ΔR.

In an embodiment, the second magnetic field generator 121 is configured to apply a fourth magnetic field to the fourth magnetoresistor R4. The fourth magnetic field includes a magnetic field component in a same direction as the second magnetic field. In a specific embodiment, the fourth magnetic field is the same as the second magnetic field.

The fourth magnetic field includes a magnetic field component opposite to a direction of the third magnetic field. In a specific embodiment, the fourth magnetic field has a direction opposite to and magnitude equal to the third magnetic field.

In the second embodiment, the preset position relationship is: a first terminal of the first magnetoresistor R1 is coupled to a power supply terminal Vd, and a first terminal of the second magnetoresistor R2 is coupled to the power supply terminal Vd.

The first magnetic field generator 111 is configured to apply a third magnetic field to the third magnetoresistor R3, and the second magnetic field generator 121 is configured to apply a fourth magnetic field to the fourth magnetoresistor R4. The fourth magnetic field includes a magnetic field component opposite to a direction of the third magnetic field. In a specific embodiment, the fourth magnetic field has magnitude equal to and direction opposite to the third magnetic field.

In a specific embodiment, as shown in FIG. 10(b), the first magnetoresistor R1 has a negative magnetoresistance effect-ΔR, the second magnetoresistor R2 has a negative magnetoresistance effect −ΔR, the third magnetoresistor R3 has a positive magnetoresistance effect +ΔR, and the fourth magnetoresistor R4 has a positive magnetoresistance effect +ΔR.

The four magnetoresistors are coupled to form a full-bridge structure, which can output a voltage value V1 at a second terminal of the first magnetoresistor R1 and a voltage value V2 at a second terminal of the second magnetoresistor R2. Specifically, the full-bridge structure can use the difference between the voltage values V1 and V2 as output to generate the calibration signal.

For example, the first magnetic field generator 111 applies a first magnetic field Br to the first magnetoresistor R1, the second magnetic field generator 121 applies a second magnetic field-Br to the second magnetoresistor R2, the first magnetic field generator 111 applies the first magnetic field Br to the third magnetoresistor R3, and the second magnetic field generator 121 applies the second magnetic field-Br to the fourth magnetoresistor R4. Since the resistance changes of the first magnetoresistor R1 and the third magnetoresistor R3 in response to magnetic fields are in opposite directions (similarly for the second magnetoresistor R2 and the fourth magnetoresistor R4), and because the resistance changes of the first magnetoresistor R1 and the second magnetoresistor R2 in response to magnetic fields are in a same direction, the full-bridge structure formed by coupling can generate a calibration signal independent of uniform ambient magnetic fields; the calibration signal has a voltage value (V1-V2).

FIG. 11 shows a third embodiment provided by the present application.

As shown in FIG. 11(a), the calibration module 100 further comprises a third magnetoresistor R3.

A first terminal of the third magnetoresistor R3 is coupled to a second terminal of the first magnetoresistor R1, and a second terminal of the third magnetoresistor R3 is coupled to a ground terminal GND.

A first terminal of the first magnetoresistor R1 is coupled to a power supply terminal Vd.

Thus, forming a half-bridge structure magnetoresistor configuration.

In an embodiment, the calibration signal is related to a voltage value V1 at a second terminal of the first magnetoresistor R1.

In an embodiment, the calibration signal is related to a voltage value V1 at a first terminal of the third magnetoresistor R3.

In an embodiment, an output node is formed between a second terminal of the first magnetoresistor R1 and a first terminal of the third magnetoresistor R3, and the output node is used to generate the calibration signal.

The third magnetoresistor R3 has a preset magnetoresistance effect relationship with the first magnetoresistor R1.

In an embodiment, the first magnetoresistor R1 has a negative magnetoresistance effect −ΔR, and the third magnetoresistor R3 has a positive magnetoresistance effect +ΔR.

In an embodiment, the first magnetoresistor R1 has a positive magnetoresistance effect +ΔR, and the third magnetoresistor R3 has a negative magnetoresistance effect −ΔR.

In an embodiment, the first magnetic field generator 111 is configured to apply a fourth magnetic field to the fourth magnetoresistor R4. The fourth magnetic field includes a magnetic field component in a same direction as the first magnetic field. In a specific embodiment, the fourth magnetic field is the same as the first magnetic field.

As shown in FIG. 11, the calibration module 100 further comprises a fourth magnetoresistor R4.

A first terminal of the fourth magnetoresistor R4 is coupled to a second terminal of the second magnetoresistor R2, and a second terminal of the fourth magnetoresistor R4 is coupled to a ground terminal GND.

A first terminal of the second magnetoresistor R2 is coupled to a power supply terminal Vd.

Thus, a second detection unit 120 has a half-bridge structure magnetoresistor configuration.

In an embodiment, the calibration signal is related to a voltage value V2 at a second terminal of the second magnetoresistor R2.

In an embodiment, the calibration signal is related to a voltage value V2 at a first terminal of the fourth magnetoresistor R4.

In an embodiment, an output node is formed between a second terminal of the second magnetoresistor R2 and a first terminal of the fourth magnetoresistor R4, and the output node is used to generate the calibration signal.

The fourth magnetoresistor R4 has a preset magnetoresistance effect relationship with the second magnetoresistor R2.

In an embodiment, the second magnetoresistor R2 has a negative magnetoresistance effect −ΔR, and the fourth magnetoresistor R4 has a positive magnetoresistance effect +ΔR.

In an embodiment, the second magnetoresistor R2 has a positive magnetoresistance effect +ΔR, and the fourth magnetoresistor R4 has a negative magnetoresistance effect −ΔR.

In an embodiment, the second magnetic field generator 121 is configured to apply a third magnetic field to the third magnetoresistor R3. The third magnetic field includes a magnetic field component in a same direction as the second magnetic field. In a specific embodiment, the third magnetic field is the same as the second magnetic field.

The third magnetic field includes a magnetic field component opposite to a direction of the fourth magnetic field. In a specific embodiment, the third magnetic field has a direction opposite to and magnitude equal to the fourth magnetic field.

The third magnetic field includes a magnetic field component in a same direction as the first magnetic field. In a specific embodiment, the third magnetic field has a direction opposite to and magnitude equal to the first magnetic field.

In the second embodiment, a preset position relationship is: a first terminal of the first magnetoresistor R1 is coupled to a power supply terminal Vd, and a first terminal of the second magnetoresistor R2 is coupled to the power supply terminal Vd.

The first magnetic field generator 111 is configured to apply a fourth magnetic field to the fourth magnetoresistor R4, and the second magnetic field generator 121 is configured to apply a third magnetic field to the third magnetoresistor R3. The third magnetic field includes a magnetic field component opposite to a direction of the fourth magnetic field. In a specific embodiment, the third magnetic field has magnitude equal to and direction opposite to the fourth magnetic field.

In a specific embodiment, as shown in FIG. 11(b), the first magnetoresistor R1 has a positive magnetoresistance effect +ΔR, the second magnetoresistor R2 has a positive magnetoresistance effect +ΔR, the third magnetoresistor R3 has a positive magnetoresistance effect +ΔR, and the fourth magnetoresistor R4 has a positive magnetoresistance effect +ΔR.

The four magnetoresistors are coupled to form a full-bridge structure, which can output a voltage value V1 at a second terminal of the first magnetoresistor R1 and a voltage value V2 at a second terminal of the second magnetoresistor R2. Specifically, the full-bridge structure can use the difference between the voltage values V1 and V2 as output to generate the calibration signal.

For example, the first magnetic field generator 111 applies a first magnetic field Br to the first magnetoresistor R1, the second magnetic field generator 121 applies a second magnetic field -Br to the second magnetoresistor R2, the first magnetic field generator 111 applies the first magnetic field Br to the fourth magnetoresistor R4, and the second magnetic field generator 121 applies the second magnetic field -Br to the third magnetoresistor R3. Since the resistance changes of the first magnetoresistor R1 and the third magnetoresistor R3 in response to magnetic fields are in a same direction (similarly for the second magnetoresistor R2 and the fourth magnetoresistor R4), and because the resistance changes of the first magnetoresistor R1 and the second magnetoresistor R2 in response to magnetic fields are in a same direction, the full-bridge structure formed by coupling can generate a calibration signal independent of uniform ambient magnetic fields; the calibration signal has a voltage value (V1-V2).

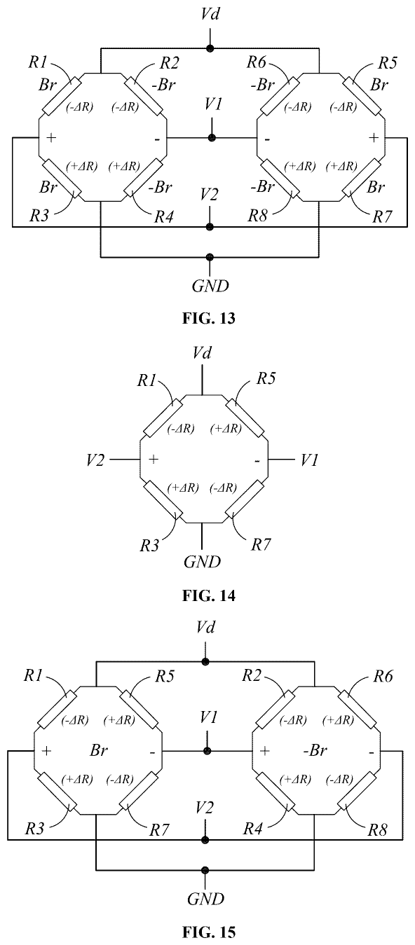

FIGS. 12 and 13 show a structure of the calibration module 100 in a fourth embodiment of the present application.

The calibration module 100 comprises a first magnetoresistor R1, a third magnetoresistor R3, a fifth magnetoresistor R5, and a seventh magnetoresistor R7.

A first terminal of the first magnetoresistor R1 is coupled to a power supply terminal Vd.

A first terminal of the third magnetoresistor R3 is coupled to a second terminal of the first magnetoresistor R1, and a second terminal of the third magnetoresistor R3 is coupled to a ground terminal GND.

A first terminal of the fifth magnetoresistor R5 is coupled to a power supply terminal Vd.

A first terminal of the seventh magnetoresistor R7 is coupled to a second terminal of the fifth magnetoresistor R5, and a second terminal of the seventh magnetoresistor R7 is coupled to a ground terminal GND.

Thus, forming a full-bridge structure magnetoresistor configuration. The full-bridge structure produces no output for uniform ambient magnetic fields.

In an embodiment, the calibration signal is related to a voltage value V2 at a second terminal of the first magnetoresistor R1.

In an embodiment, the calibration signal is related to a voltage value V2 at a first terminal of the third magnetoresistor R3.

In an embodiment, the calibration signal is related to a voltage value V2 at a second terminal of the fifth magnetoresistor R5.

In an embodiment, the calibration signal is related to a voltage value V2 at a first terminal of the seventh magnetoresistor R7.

In an embodiment, an output node is formed between a second terminal of the first magnetoresistor R1 and a first terminal of the third magnetoresistor R3, and the output node is used to generate the calibration signal.

In an embodiment, an output node is formed between a second terminal of the fifth magnetoresistor R5 and a first terminal of the seventh magnetoresistor R7, and the output node is used to generate the calibration signal.

In an embodiment, a second terminal of the first magnetoresistor R1 is coupled to a second terminal of the fifth magnetoresistor R5 to generate the calibration signal.

In an embodiment, a first terminal of the third magnetoresistor R3 is coupled to a first terminal of the seventh magnetoresistor R7 to generate the calibration signal.

The first magnetoresistor R1, third magnetoresistor R3, fifth magnetoresistor R5, and seventh magnetoresistor R7 have a preset magnetoresistance effect relationship.

In an embodiment, the first magnetoresistor R1 has a negative magnetoresistance effect −ΔR, the third magnetoresistor R3 has a positive magnetoresistance effect +ΔR, the fifth magnetoresistor R5 has a negative magnetoresistance effect −ΔR, and the seventh magnetoresistor R7 has a positive magnetoresistance effect +ΔR.

In an embodiment, the first magnetoresistor R1 has a positive magnetoresistance effect +ΔR, the third magnetoresistor R3 has a negative magnetoresistance effect −ΔR, the fifth magnetoresistor R5 has a positive magnetoresistance effect +ΔR, and the seventh magnetoresistor R7 has a negative magnetoresistance effect −ΔR.

In an embodiment, the first magnetic field generator 111 is configured to apply a third magnetic field to the third magnetoresistor R3. The third magnetic field includes a magnetic field component in a same direction as the first magnetic field. In a specific embodiment, the third magnetic field is the same as the first magnetic field.

In an embodiment, the first magnetic field generator 111 is configured to apply a fifth magnetic field to the fifth magnetoresistor R5. The fifth magnetic field includes a magnetic field component in a same direction as the first magnetic field. In a specific embodiment, the fifth magnetic field is the same as the first magnetic field.

In an embodiment, the first magnetic field generator 111 is configured to apply a seventh magnetic field to the seventh magnetoresistor R7. The seventh magnetic field includes a magnetic field component in a same direction as the fifth magnetic field. In a specific embodiment, the seventh magnetic field is the same as the fifth magnetic field.

As shown in FIG. 13, the calibration module 100 comprises a second magnetoresistor R2, a fourth magnetoresistor R4, a sixth magnetoresistor R6, and an eighth magnetoresistor R8.

A first terminal of the second magnetoresistor R2 is coupled to a power supply terminal Vd.

A first terminal of the fourth magnetoresistor R4 is coupled to a second terminal of the second magnetoresistor R2, and a second terminal of the fourth magnetoresistor R4 is coupled to a ground terminal GND.

A first terminal of the sixth magnetoresistor R6 is coupled to a power supply terminal Vd.

A first terminal of the eighth magnetoresistor R8 is coupled to a second terminal of the sixth magnetoresistor R6, and a second terminal of the eighth magnetoresistor R8 is coupled to a ground terminal GND.

Thus, forming a full-bridge structure magnetoresistor configuration.

In an embodiment, the calibration signal is related to a voltage value V1 at a second terminal of the second magnetoresistor R2.

In an embodiment, the calibration signal is related to a voltage value V1 at a first terminal of the fourth magnetoresistor R4.

In an embodiment, the calibration signal is related to a voltage value V1 at a second terminal of the sixth magnetoresistor R6.

In an embodiment, the calibration signal is related to a voltage value V1 at a first terminal of the eighth magnetoresistor R8.

In an embodiment, an output node is formed between a second terminal of the second magnetoresistor R2 and a first terminal of the fourth magnetoresistor R4, and the output node is used to generate the calibration signal.

In an embodiment, an output node is formed between a second terminal of the sixth magnetoresistor R6 and a first terminal of the eighth magnetoresistor R8, and the output node is used to generate the calibration signal.

In an embodiment, a second terminal of the second magnetoresistor R2 is coupled to a second terminal of the sixth magnetoresistor R6 to generate the calibration signal.

In an embodiment, a first terminal of the fourth magnetoresistor R4 is coupled to a first terminal of the eighth magnetoresistor R8 to generate the calibration signal.

The second magnetoresistor R2, fourth magnetoresistor R4, sixth magnetoresistor R6, and eighth magnetoresistor R8 have a preset magnetoresistance effect relationship.

In an embodiment, the second magnetoresistor R2 has a negative magnetoresistance effect −ΔR, the fourth magnetoresistor R4 has a positive magnetoresistance effect +ΔR, the sixth magnetoresistor R6 has a negative magnetoresistance effect −ΔR, and the eighth magnetoresistor R8 has a positive magnetoresistance effect +ΔR.

In an embodiment, the second magnetoresistor R2 has a positive magnetoresistance effect +ΔR, the fourth magnetoresistor R4 has a negative magnetoresistance effect −ΔR, the sixth magnetoresistor R6 has a positive magnetoresistance effect +ΔR, and the eighth magnetoresistor R8 has a negative magnetoresistance effect −ΔR.

In an embodiment, the second magnetic field generator 121 is configured to apply a fourth magnetic field to the fourth magnetoresistor R4. The fourth magnetic field includes a magnetic field component in a same direction as the second magnetic field. In a specific embodiment, the fourth magnetic field is the same as the second magnetic field.

The fourth magnetic field includes a magnetic field component opposite to a direction of the third magnetic field. In a specific embodiment, the fourth magnetic field has a direction opposite to and magnitude equal to the third magnetic field.

In an embodiment, the second magnetic field generator 121 is configured to apply a sixth magnetic field to the sixth magnetoresistor R6. The sixth magnetic field includes a magnetic field component in a same direction as the second magnetic field. In a specific embodiment, the sixth magnetic field is the same as the second magnetic field.

The sixth magnetic field includes a magnetic field component opposite to a direction of the fifth magnetic field. In a specific embodiment, the sixth magnetic field has a direction opposite to and magnitude equal to the fifth magnetic field.

In an embodiment, the second magnetic field generator 121 is configured to apply an eighth magnetic field to the eighth magnetoresistor R8. The eighth magnetic field includes a magnetic field component in a same direction as the sixth magnetic field. In a specific embodiment, the eighth magnetic field is the same as the sixth magnetic field.

The eighth magnetic field includes a magnetic field component opposite to a direction of the seventh magnetic field. In a specific embodiment, the eighth magnetic field has a direction opposite to and magnitude equal to the seventh magnetic field.

In the fourth embodiment, the preset position relationship is: a first terminal of the first magnetoresistor R1 is coupled to a power supply terminal Vd, and a first terminal of the second magnetoresistor R2 is coupled to the power supply terminal Vd.

The first magnetic field generator 111 is configured to apply a third magnetic field to the third magnetoresistor R3, and the second magnetic field generator 121 is configured to apply a fourth magnetic field to the fourth magnetoresistor R4. The fourth magnetic field includes a magnetic field component opposite to a direction of the third magnetic field. In a specific embodiment, the third magnetic field has magnitude equal to and direction opposite to the fourth magnetic field.

The first magnetic field generator 111 is configured to apply a fifth magnetic field to the fifth magnetoresistor R5, and the second magnetic field generator 121 is configured to apply a sixth magnetic field to the sixth magnetoresistor R6. The sixth magnetic field includes a magnetic field component opposite to a direction of the fifth magnetic field. In a specific embodiment, the sixth magnetic field has magnitude equal to and direction opposite to the fifth magnetic field.

The first magnetic field generator 111 is configured to apply a seventh magnetic field to the seventh magnetoresistor R7, and the second magnetic field generator 121 is configured to apply an eighth magnetic field to the eighth magnetoresistor R8. The eighth magnetic field includes a magnetic field component opposite to a direction of the seventh magnetic field. In a specific embodiment, the eighth magnetic field has magnitude equal to and direction opposite to the seventh magnetic field.

In a specific embodiment, as shown in FIG. 13, the first magnetoresistor R1 has a negative magnetoresistance effect −ΔR, the second magnetoresistor R2 has a negative magnetoresistance effect −ΔR, the third magnetoresistor R3 has a positive magnetoresistance effect +ΔR, the fourth magnetoresistor R4 has a positive magnetoresistance effect +ΔR, the fifth magnetoresistor R5 has a negative magnetoresistance effect −ΔR, the sixth magnetoresistor R6 has a negative magnetoresistance effect −ΔR, the seventh magnetoresistor R7 has a positive magnetoresistance effect +ΔR, and the eighth magnetoresistor R8 has a positive magnetoresistance effect +ΔR.

The eight magnetoresistors are coupled to form a double full-bridge structure, which can output a voltage value V2 at a coupling point between a second terminal of the first magnetoresistor R1 and a second terminal of the fifth magnetoresistor R5, and a voltage value V1 at a coupling point between a second terminal of the second magnetoresistor R2 and a second terminal of the sixth magnetoresistor R6. Specifically, the full-bridge structure can use the difference between the voltage values V1 and V2 as output to generate the calibration signal.

For example, the first magnetic field generator 111 applies a first magnetic field Br to the first magnetoresistor R1, the second magnetic field generator 121 applies a second magnetic field -Br to the second magnetoresistor R2, the first magnetic field generator 111 applies the first magnetic field Br to the third magnetoresistor R3, the second magnetic field generator 121 applies the second magnetic field-Br to the fourth magnetoresistor R4, the first magnetic field generator 111 applies the first magnetic field Br to the fifth magnetoresistor R5, the second magnetic field generator 121 applies the second magnetic field -Br to the sixth magnetoresistor R6, the first magnetic field generator 111 applies the first magnetic field Br to the seventh magnetoresistor R7, and the second magnetic field generator 121 applies the second magnetic field -Br to the eighth magnetoresistor R8. Since the calibration module 100 produces no output for uniform ambient magnetic fields, the double full-bridge structure formed by coupling can generate a calibration signal independent of uniform ambient magnetic fields; the calibration signal has a voltage value (V1-V2).

FIGS. 14 and 15 show a structure of the calibration module 100 in a fifth embodiment of the present application.

The calibration module 100 comprises a first magnetoresistor R1, a third magnetoresistor R3, a fifth magnetoresistor R5, and a seventh magnetoresistor R7.

A first terminal of the first magnetoresistor R1 is coupled to a power supply terminal Vd.

A first terminal of the third magnetoresistor R3 is coupled to a second terminal of the first magnetoresistor R1, and a second terminal of the third magnetoresistor R3 is coupled to a ground terminal GND.

A first terminal of the fifth magnetoresistor R5 is coupled to a power supply terminal Vd.

A first terminal of the seventh magnetoresistor R7 is coupled to a second terminal of the fifth magnetoresistor R5, and a second terminal of the seventh magnetoresistor R7 is coupled to a ground terminal GND.

Thus, forming a full-bridge structure magnetoresistor configuration.

In an embodiment, the calibration signal is related to a voltage value V2 at a second terminal of the first magnetoresistor R1.

In an embodiment, the calibration signal is related to a voltage value V2 at a first terminal of the third magnetoresistor R3.

In an embodiment, the calibration signal is related to a voltage value V1 at a second terminal of the fifth magnetoresistor R5.

In an embodiment, the calibration signal is related to a voltage value V1 at a first terminal of the seventh magnetoresistor R7.

In an embodiment, an output node is formed between a second terminal of the first magnetoresistor R1 and a first terminal of the third magnetoresistor R3, and the output node is used to generate the calibration signal.

In an embodiment, an output node is formed between a second terminal of the fifth magnetoresistor R5 and a first terminal of the seventh magnetoresistor R7, and the output node is used to generate the calibration signal.

The first magnetoresistor R1, third magnetoresistor R3, fifth magnetoresistor R5, and seventh magnetoresistor R7 have a preset magnetoresistance effect relationship.

In an embodiment, the first magnetoresistor R1 has a negative magnetoresistance effect −ΔR, the third magnetoresistor R3 has a positive magnetoresistance effect +ΔR, the fifth magnetoresistor R5 has a positive magnetoresistance effect +ΔR, and the seventh magnetoresistor R7 has a negative magnetoresistance effect −ΔR.

In an embodiment, the first magnetoresistor R1 has a positive magnetoresistance effect +ΔR, the third magnetoresistor R3 has a negative magnetoresistance effect −ΔR, the fifth magnetoresistor R5 has a negative magnetoresistance effect −ΔR, and the seventh magnetoresistor R7 has a positive magnetoresistance effect +ΔR.

In an embodiment, the first magnetic field generator 111 is configured to apply a third magnetic field to the third magnetoresistor R3. The third magnetic field includes a magnetic field component in a same direction as the first magnetic field. In a specific embodiment, the third magnetic field is the same as the first magnetic field.

In an embodiment, the first magnetic field generator 111 is configured to apply a fifth magnetic field to the fifth magnetoresistor R5. The fifth magnetic field includes a magnetic field component in a same direction as the first magnetic field. In a specific embodiment, the fifth magnetic field is the same as the first magnetic field.

In an embodiment, the first magnetic field generator 111 is configured to apply a seventh magnetic field to the seventh magnetoresistor R7. The seventh magnetic field includes a magnetic field component in a same direction as the fifth magnetic field. In a specific embodiment, the seventh magnetic field is the same as the fifth magnetic field.

As shown in FIG. 15, the calibration module 100 comprises a second magnetoresistor R2, a fourth magnetoresistor R4, a sixth magnetoresistor R6, and an eighth magnetoresistor R8.

A first terminal of the second magnetoresistor R2 is coupled to a power supply terminal Vd.

A first terminal of the fourth magnetoresistor R4 is coupled to a second terminal of the second magnetoresistor R2, and a second terminal of the fourth magnetoresistor R4 is coupled to a ground terminal GND.

A first terminal of the sixth magnetoresistor R6 is coupled to a power supply terminal Vd.

A first terminal of the eighth magnetoresistor R8 is coupled to a second terminal of the sixth magnetoresistor R6, and a second terminal of the eighth magnetoresistor R8 is coupled to a ground terminal GND.

Thus, forming a full-bridge structure magnetoresistor configuration.

In an embodiment, the calibration signal is related to a voltage value V1 at a second terminal of the second magnetoresistor R2.

In an embodiment, the calibration signal is related to a voltage value V1 at a first terminal of the fourth magnetoresistor R4.

In an embodiment, the calibration signal is related to a voltage value V2 at a second terminal of the sixth magnetoresistor R6.

In an embodiment, the calibration signal is related to a voltage value V2 at a first terminal of the eighth magnetoresistor R8.

In an embodiment, an output node is formed between a second terminal of the second magnetoresistor R2 and a first terminal of the fourth magnetoresistor R4, and the output node is used to generate the calibration signal.

In an embodiment, an output node is formed between a second terminal of the sixth magnetoresistor R6 and a first terminal of the eighth magnetoresistor R8, and the output node is used to generate the calibration signal.

The second magnetoresistor R2, fourth magnetoresistor R4, sixth magnetoresistor R6, and eighth magnetoresistor R8 have a preset magnetoresistance effect relationship.

In an embodiment, the second magnetoresistor R2 has a negative magnetoresistance effect −ΔR, the fourth magnetoresistor R4 has a positive magnetoresistance effect +ΔR, the sixth magnetoresistor R6 has a positive magnetoresistance effect +ΔR, and the eighth magnetoresistor R8 has a negative magnetoresistance effect −ΔR.

In an embodiment, the second magnetoresistor R2 has a positive magnetoresistance effect +ΔR, the fourth magnetoresistor R4 has a negative magnetoresistance effect −ΔR, the sixth magnetoresistor R6 has a negative magnetoresistance effect −ΔR, and the eighth magnetoresistor R8 has a positive magnetoresistance effect +ΔR.

In an embodiment, the second magnetic field generator 121 is configured to apply a fourth magnetic field to the fourth magnetoresistor R4. The fourth magnetic field includes a magnetic field component in a same direction as the second magnetic field. In a specific embodiment, the fourth magnetic field is the same as the second magnetic field.

The fourth magnetic field includes a magnetic field component opposite to a direction of the third magnetic field. In a specific embodiment, the fourth magnetic field has a direction opposite to and magnitude equal to the third magnetic field.

In an embodiment, the second magnetic field generator 121 is configured to apply a sixth magnetic field to the sixth magnetoresistor R6. The sixth magnetic field includes a magnetic field component in a same direction as the second magnetic field. In a specific embodiment, the sixth magnetic field is the same as the second magnetic field.

The sixth magnetic field includes a magnetic field component opposite to a direction of the fifth magnetic field. In a specific embodiment, the sixth magnetic field has a direction opposite to and magnitude equal to the fifth magnetic field.

In an embodiment, the second magnetic field generator 121 is configured to apply an eighth magnetic field to the eighth magnetoresistor R8. The eighth magnetic field includes a magnetic field component in a same direction as the sixth magnetic field. In a specific embodiment, the eighth magnetic field is the same as the sixth magnetic field.

The eighth magnetic field includes a magnetic field component opposite to a direction of the seventh magnetic field. In a specific embodiment, the eighth magnetic field has a direction opposite to and magnitude equal to the seventh magnetic field.

In the fifth embodiment, the preset position relationship is: a first terminal of the first magnetoresistor R1 is coupled to a power supply terminal Vd, and a first terminal of the second magnetoresistor R2 is coupled to the power supply terminal Vd.

The first magnetic field generator 111 is configured to apply a third magnetic field to the third magnetoresistor R3, and the second magnetic field generator 121 is configured to apply a fourth magnetic field to the fourth magnetoresistor R4. The fourth magnetic field includes a magnetic field component opposite to a direction of the third magnetic field. In a specific embodiment, the third magnetic field has magnitude equal to and direction opposite to the fourth magnetic field.

The first magnetic field generator 111 is configured to apply a fifth magnetic field to the fifth magnetoresistor R5, and the second magnetic field generator 121 is configured to apply a sixth magnetic field to the sixth magnetoresistor R6. The sixth magnetic field includes a magnetic field component opposite to a direction of the fifth magnetic field. In a specific embodiment, the sixth magnetic field has magnitude equal to and direction opposite to the fifth magnetic field.

The first magnetic field generator 111 is configured to apply a seventh magnetic field to the seventh magnetoresistor R7, and the second magnetic field generator 121 is configured to apply an eighth magnetic field to the eighth magnetoresistor R8. The eighth magnetic field includes a magnetic field component opposite to a direction of the seventh magnetic field. In a specific embodiment, the eighth magnetic field has magnitude equal to and direction opposite to the seventh magnetic field.

In a specific embodiment, as shown in FIG. 15, the first magnetoresistor R1 has a negative magnetoresistance effect −ΔR, the second magnetoresistor R2 has a negative magnetoresistance effect −ΔR, the third magnetoresistor R3 has a positive magnetoresistance effect +ΔR, the fourth magnetoresistor R4 has a positive magnetoresistance effect +ΔR, the fifth magnetoresistor R5 has a positive magnetoresistance effect +ΔR, the sixth magnetoresistor R6 has a positive magnetoresistance effect +ΔR, the seventh magnetoresistor R7 has a negative magnetoresistance effect −ΔR, and the eighth magnetoresistor R8 has a negative magnetoresistance effect −ΔR.

The eight magnetoresistors are coupled to form a double full-bridge structure. In an embodiment, a second terminal of the first magnetoresistor R1 is coupled to a second terminal of the sixth magnetoresistor R6; a second terminal of the fifth magnetoresistor R5 is coupled to a second terminal of the second magnetoresistor R2 to generate the calibration signal.

A voltage value V2 at a coupling point between a second terminal of the first magnetoresistor R1 and a second terminal of the sixth magnetoresistor R6, and a voltage value V1 at a coupling point between a second terminal of the second magnetoresistor R2 and a second terminal of the fifth magnetoresistor R5 can be used as output.

After the first magnetic field generator 111 and the second magnetic field generator 121 apply magnetic fields, the full-bridge structure can use the difference between the voltage values V1 and V2 as output to generate the calibration signal.

For example, the first magnetic field generator 111 applies a first magnetic field Br to the first magnetoresistor R1, third magnetoresistor R3, fifth magnetoresistor R5, and seventh magnetoresistor R7, while the second magnetic field generator 121 applies a second magnetic field -Br to the second magnetoresistor R2, fourth magnetoresistor R4, sixth magnetoresistor R6, and eighth magnetoresistor R8. Since the output of the calibration module 100 in response to uniform ambient magnetic fields is in a same direction, the double full-bridge structure formed by coupling can generate a calibration signal independent of uniform ambient magnetic fields; the calibration signal has a voltage value (V1-V2).

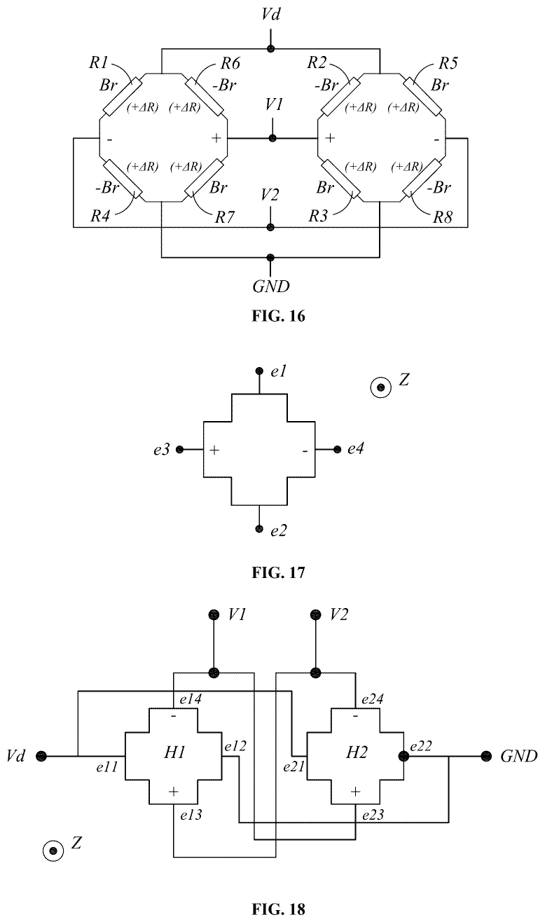

FIG. 16 shows a structure of the calibration module 100 in a sixth embodiment of the present application.

The calibration module 100 comprises a first magnetoresistor R1 and a seventh magnetoresistor R7.

A first terminal of the first magnetoresistor R1 is coupled to a power supply terminal Vd.

A second terminal of the seventh magnetoresistor R7 is coupled to a ground terminal GND.

The calibration module 100 comprises a fourth magnetoresistor R4 and a sixth magnetoresistor R6.

A first terminal of the fourth magnetoresistor R4 is coupled to a second terminal of the first magnetoresistor R1, and a second terminal of the fourth magnetoresistor R4 is coupled to the ground terminal GND.

A first terminal of the sixth magnetoresistor R6 is coupled to a power supply terminal Vd.

A first terminal of the seventh magnetoresistor R7 is coupled to a second terminal of the sixth magnetoresistor R6.

Thus, the first magnetoresistor R1, fourth magnetoresistor R4, sixth magnetoresistor R6, and seventh magnetoresistor R7 are coupled to form a full-bridge structure. The full-bridge structure produces no output for uniform ambient magnetic fields.

In an embodiment, the calibration signal is related to a voltage value V2 at a second terminal of the first magnetoresistor R1.

In an embodiment, the calibration signal is related to a voltage value V2 at a first terminal of the fourth magnetoresistor R4.

In an embodiment, the calibration signal is related to a voltage value V1 at a second terminal of the sixth magnetoresistor R6.

In an embodiment, the calibration signal is related to a voltage value V1 at a first terminal of the seventh magnetoresistor R7.

In an embodiment, an output node is formed between a second terminal of the first magnetoresistor R1 and a first terminal of the fourth magnetoresistor R4, and the output node is used to generate the calibration signal.

In an embodiment, an output node is formed between a second terminal of the sixth magnetoresistor R6 and a first terminal of the seventh magnetoresistor R7, and the output node is used to generate the calibration signal.

The first magnetoresistor R1, fourth magnetoresistor R4, sixth magnetoresistor R6, and seventh magnetoresistor R7 have a preset magnetoresistance effect relationship.

In an embodiment, the first magnetoresistor R1 has a positive magnetoresistance effect +ΔR, the fourth magnetoresistor R4 has a positive magnetoresistance effect +ΔR, the sixth magnetoresistor R6 has a positive magnetoresistance effect +ΔR, and the seventh magnetoresistor R7 has a positive magnetoresistance effect +ΔR.

In an embodiment, the first magnetoresistor R1 has a negative magnetoresistance effect −ΔR, the fourth magnetoresistor R4 has a negative magnetoresistance effect −ΔR, the sixth magnetoresistor R6 has a negative magnetoresistance effect −ΔR, and the seventh magnetoresistor R7 has a negative magnetoresistance effect −ΔR.

In an embodiment, the second magnetic field generator 121 is configured to apply a fourth magnetic field to the fourth magnetoresistor R4. The fourth magnetic field includes a magnetic field component opposite to the direction of the first magnetic field. In a specific embodiment, the fourth magnetic field has magnitude equal to and direction opposite to the first magnetic field.

In an embodiment, the second magnetic field generator 121 is configured to apply a sixth magnetic field to the sixth magnetoresistor R6. The sixth magnetic field includes a magnetic field component in a same direction as the fourth magnetic field. In a specific embodiment, the sixth magnetic field is the same as the fourth magnetic field.

In an embodiment, the first magnetic field generator 111 is configured to apply a seventh magnetic field to the seventh magnetoresistor R7. The seventh magnetic field includes a magnetic field component in a same direction as the first magnetic field. In a specific embodiment, the seventh magnetic field is the same as to the first magnetic field.

In an embodiment, another set of magnetoresistors may form a full-bridge structure magnetoresistor configuration. The full-bridge structure produces no output for uniform ambient magnetic fields. Notably, the configurations of the two full-bridge structures may be the same.

As shown in FIG. 16, the calibration module 100 comprises a third magnetoresistor R3 and a fifth magnetoresistor R5.

A second terminal of the third magnetoresistor R3 is coupled to a ground terminal GND.

A first terminal of the fifth magnetoresistor R5 is coupled to a power supply terminal Vd.

The calibration module 100 comprises a second magnetoresistor R2 and an eighth magnetoresistor R8.

A first terminal of the second magnetoresistor R2 is coupled to a power supply terminal Vd, and a second terminal of the second magnetoresistor R2 is coupled to a first terminal of the third magnetoresistor R3.

A first terminal of the eighth magnetoresistor R8 is coupled to a second terminal of the sixth magnetoresistor R6, and a second terminal of the eighth magnetoresistor R8 is coupled to a ground terminal GND.

Thus, the second magnetoresistor R2, third magnetoresistor R3, fifth magnetoresistor R5, and eighth magnetoresistor R8 are coupled to form a full-bridge structure. The full-bridge structure produces no output for uniform ambient magnetic fields.

In an embodiment, the calibration signal is related to a voltage value V1 at a second terminal of the second magnetoresistor R2.

In an embodiment, the calibration signal is related to a voltage value V1 at a first terminal of the third magnetoresistor R3.

In an embodiment, the calibration signal is related to a voltage value V2 at a second terminal of the fifth magnetoresistor R5.

In an embodiment, the calibration signal is related to a voltage value V2 at a first terminal of the eighth magnetoresistor R8.

In an embodiment, an output node is formed between a second terminal of the second magnetoresistor R2 and a first terminal of the third magnetoresistor R3, and the output node is used to generate the calibration signal.

In an embodiment, an output node is formed between a second terminal of the fifth magnetoresistor R5 and a first terminal of the eighth magnetoresistor R8 is used to generate the calibration signal.

The second magnetoresistor R2, third magnetoresistor R3, fifth magnetoresistor R5, and eighth magnetoresistor R8 have a preset magnetoresistance effect relationship.

In an embodiment, the second magnetoresistor R2 has a positive magnetoresistance effect +ΔR, the third magnetoresistor R3 has a positive magnetoresistance effect +ΔR, the fifth magnetoresistor R5 has a positive magnetoresistance effect +ΔR, and the eighth magnetoresistor R8 has a positive magnetoresistance effect +ΔR.

In an embodiment, the second magnetoresistor R2 has a negative magnetoresistance effect −ΔR, the third magnetoresistor R3 has a negative magnetoresistance effect −ΔR, the fifth magnetoresistor R5 has a negative magnetoresistance effect −ΔR, and the eighth magnetoresistor R8 has a negative magnetoresistance effect −ΔR.

In an embodiment, the first magnetic field generator 111 is configured to apply a third magnetic field to the third magnetoresistor R3. The third magnetic field includes a magnetic field component opposite to the direction of the second magnetic field. In a specific embodiment, the third magnetic field has magnitude equal to and direction opposite to the second magnetic field.

The fourth magnetic field includes a magnetic field component opposite to a direction of the third magnetic field. In a specific embodiment, the fourth magnetic field has magnitude equal to and direction opposite to the third magnetic field.

The third magnetic field includes a magnetic field component in a same direction as the first magnetic field. In a specific embodiment, the third magnetic field is the same as the first magnetic field.

In an embodiment, the first magnetic field generator 111 is configured to apply a fifth magnetic field to the fifth magnetoresistor R5. The fifth magnetic field includes a magnetic field component in a same direction as the third magnetic field. In a specific embodiment, the fifth magnetic field is the same as to the third magnetic field.

The sixth magnetic field includes a magnetic field component opposite to a direction of the fifth magnetic field. In a specific embodiment, the sixth magnetic field has magnitude equal to and direction opposite to the fifth magnetic field.

In an embodiment, the second magnetic field generator 121 is configured to apply an eighth magnetic field to the eighth magnetoresistor R8. The eighth magnetic field includes a magnetic field component in a same direction as the second magnetic field. In a specific embodiment, the eighth magnetic field is the same as the second magnetic field.

The eighth magnetic field includes a magnetic field component opposite to a direction of the seventh magnetic field. In a specific embodiment, the eighth magnetic field has magnitude equal to and direction opposite to the seventh magnetic field.

The seventh magnetic field includes a magnetic field component in a same direction as the fifth magnetic field. In a specific embodiment, the seventh magnetic field is the same as the fifth magnetic field.

In the sixth embodiment, the preset position relationship is: a first terminal of the first magnetoresistor R1 is coupled to a power supply terminal Vd, and a first terminal of the second magnetoresistor R2 is coupled to the power supply terminal Vd.

The first magnetic field generator 111 is configured to apply a third magnetic field to the third magnetoresistor R3, and the second magnetic field generator 121 is configured to apply a fourth magnetic field to the fourth magnetoresistor R4. The fourth magnetic field includes a magnetic field component opposite to a direction of the third magnetic field. In a specific embodiment, the third magnetic field has magnitude equal to and direction opposite to the fourth magnetic field.

The third magnetic field includes a magnetic field component identical to the first magnetic field. In a specific embodiment, the third magnetic field is identical to the first magnetic field.

The first magnetic field generator 111 is configured to apply a fifth magnetic field to the fifth magnetoresistor R5, and the second magnetic field generator 121 is configured to apply a sixth magnetic field to the sixth magnetoresistor R6. The sixth magnetic field includes a magnetic field component opposite to a direction of the fifth magnetic field. In a specific embodiment, the fifth magnetic field has magnitude equal to and direction opposite to the sixth magnetic field.

The first magnetic field generator 111 is configured to apply a seventh magnetic field to the seventh magnetoresistor R7, and the second magnetic field generator 121 is configured to apply an eighth magnetic field to the eighth magnetoresistor R8. The eighth magnetic field includes a magnetic field component opposite to a direction of the seventh magnetic field. In a specific embodiment, the seventh magnetic field has magnitude equal to and direction opposite to the sixth magnetic field to the eighth magnetic field.

The seventh magnetic field includes a magnetic field component in a same direction as the fifth magnetic field. In a specific embodiment, the seventh magnetic field is the same as the fifth magnetic field.

In a specific embodiment, as shown in FIG. 16, the first magnetoresistor R1 has a positive magnetoresistance effect +ΔR, the second magnetoresistor R2 has a positive magnetoresistance effect +ΔR, the third magnetoresistor R3 has a positive magnetoresistance effect +ΔR, the fourth magnetoresistor R4 has a positive magnetoresistance effect +ΔR, the fifth magnetoresistor R5 has a positive magnetoresistance effect +ΔR, the sixth magnetoresistor R6 has a positive magnetoresistance effect +ΔR, the seventh magnetoresistor R7 has a positive magnetoresistance effect +ΔR, and the eighth magnetoresistor R8 has a positive magnetoresistance effect +ΔR.

The eight magnetoresistors are coupled to form a double full-bridge structure. In an embodiment, a second terminal of the first magnetoresistor R1 is coupled to a second terminal of the fifth magnetoresistor R5, and a second terminal of the second magnetoresistor R2 is coupled to a second terminal of the sixth magnetoresistor R6 to generate the calibration signal.

A voltage value V2 at a coupling point between a second terminal of the first magnetoresistor R1 and a second terminal of the fifth magnetoresistor R5, and a voltage value V1 at a coupling point between a second terminal of the second magnetoresistor R2 and a second terminal of the sixth magnetoresistor R6 can be used as output.

After the first magnetic field generator 111 and the second magnetic field generator 121 apply magnetic fields, the full-bridge structure can use the difference between the voltage values V1 and V2 as output to generate the calibration signal.

For example, the first magnetic field generator 111 applies a first magnetic field Br to the first magnetoresistor R1, the second magnetic field generator 121 applies a second magnetic field -Br to the second magnetoresistor R2, the first magnetic field generator 111 applies a first magnetic field Br to the third magnetoresistor R3, the second magnetic field generator 121 applies a second magnetic field-Br to the fourth magnetoresistor R4, the first magnetic field generator 111 applies a first magnetic field Br to the fifth magnetoresistor R5, the second magnetic field generator 121 applies a second magnetic field-Br to the sixth magnetoresistor R6, the first magnetic field generator 111 applies a first magnetic field Br to the seventh magnetoresistor R7, and the second magnetic field generator 121 applies a second magnetic field -Br to the eighth magnetoresistor R8. Since the calibration module 100 produces no output in response to uniform ambient magnetic fields, the double full-bridge structure formed by coupling can generate a calibration signal independent of uniform ambient magnetic fields; the calibration signal has a voltage value of (V1-V2).

FIGS. 17 and 18 show a structure of the calibration module 100 in a seventh embodiment of the present application.

The calibration module 100 comprises a first Hall unit H1.

The detection direction of the first Hall unit H1 is perpendicular to a mounting plane of the Hall unit (e.g., the first Hall unit H1). In an embodiment, the detection direction of the first Hall unit H1 is a third direction Z. The detection direction of the first Hall unit H1 indicates that the first Hall unit H1 is sensitive to magnetic field changes in the direction.

A first terminal e11 of the first Hall unit H1 is coupled to a power supply terminal Vd. A second terminal e12 of the first Hall unit H1 is coupled to a ground terminal GND.

The first Hall unit H1 further includes a third terminal e13 and a fourth terminal e14. When the first Hall unit H1 is energized and a magnetic field along a Z-direction is applied, charges deflect due to the Lorentz force, generating a potential difference between the third terminal e13 and the fourth terminal e14.

The calibration module 100 comprises a second Hall unit H2.

The detection direction of the second Hall unit H2 is perpendicular to a mounting plane of the Hall unit (e.g., the second Hall unit H2). In an embodiment, the detection direction of the second Hall unit H2 is a third direction Z. The detection direction of the second Hall unit H2 indicates that the second Hall unit H2 is sensitive to magnetic field changes in the direction.

A first terminal e21 of the second Hall unit H2 is coupled to the power supply terminal Vd. A second terminal e22 of the second Hall unit H2 is coupled to the ground terminal GND.

The second Hall unit H2 further includes a third terminal e23 and a fourth terminal e24. When the second Hall unit H2 is energized and a magnetic field along a Z-direction is applied, charges deflect due to the Lorentz force, generating a potential difference between the third terminal e23 and the fourth terminal e24.

The third terminal e23 of the second Hall unit H2 is coupled to the fourth terminal e14 of the first Hall unit H1, and the fourth terminal e24 of the second Hall unit H2 is coupled to the third terminal e13 of the first Hall unit H1. The configuration forms a double Hall structure that produces no output for uniform ambient magnetic fields.

A voltage value V1 at a coupling point between the fourth terminal e14 of the first Hall unit H1 and the third terminal e23 of the second Hall unit H2, and a voltage value V2 at a coupling point between the third terminal e13 of the first Hall unit H1 and the fourth terminal e24 of the second Hall unit H2 can be used as outputs.

After the first magnetic field generator 111 and the second magnetic field generator 121 apply magnetic fields, the double Hall structure can use the difference between the voltage values V1 and V2 as output to generate the calibration signal.

For example, the first magnetic field generator 111 applies a first magnetic field Br to the first Hall unit H1, and the second magnetic field generator 121 applies a second magnetic field -Br to the second Hall unit H2. Since the calibration module 100 produces outputs in the same direction in response to uniform ambient magnetic fields, the coupled dual-Hall structure generates a calibration signal independent of uniform ambient magnetic fields. The calibration signal has a voltage value of (V1-V2).

In summary, the magnetic field detection apparatus provided by the present application achieves the following: By employing independent detection and calibration modules, it avoids bandwidth limitations caused by alternating detection and calibration steps. Adjusting the magnitude of a magnetic field detection signal at the detection module based on a value of a reference signal enables numerical-level calibration to eliminate linear errors. By configuring the reference signal to be independent of uniform ambient magnetic fields, it prevents the reference signal or the calibration module generating it from being affected by ambient magnetic fields, thereby preserving the overall performance of the apparatus. Specifically, the configuration provided by the present application avoids detection range contraction caused by power consumption constraints.

It should be understood that although this specification describes the application through specific embodiments, each embodiment is not limited to containing only one independent technical solution. This narrative style is adopted solely for clarity, and those skilled in the art should treat the specification as a whole. Technical solutions across different embodiments may also be appropriately combined to form other implementations understandable to those skilled in the art.

The detailed descriptions provided above are merely specific explanations of feasible embodiments of the present application and do not limit its protection scope. Any equivalent implementations or modifications derived without departing from the technical spirit of the application shall fall within the protection scope of the present application.

What is claimed is:

1. A magnetic field detection apparatus, wherein comprising:
a detection module, configured to generate a magnetic field detection signal; and
a calibration module, configured to generate a reference signal; the reference signal is configured to calibrate the magnetic field detection signal, and the reference signal is independent of a uniform ambient magnetic field;
when a value of the reference signal satisfies a first relationship with a first preset value, the magnetic field detection signal is amplified; or,
when a value of the reference signal satisfies a second relationship with a second preset value, the magnetic field detection signal is attenuated.

2. The magnetic field detection apparatus according to claim 1, wherein the first relationship includes that the value of the reference signal is less than the first preset value; the amplification of the magnetic field detection signal includes at least one of:
increasing a driving current input to the detection module;
increasing a driving voltage input to the detection module;
increasing an amplification factor for generating the magnetic field detection signal;
increasing an operational gain of the detection signal.

3. The magnetic field detection apparatus according to claim 1, wherein the second relationship includes that the value of the reference signal is greater than the second preset value; the attenuation of the magnetic field detection signal includes at least one of:
decreasing a driving current input to the detection module;
decreasing a driving voltage input to the detection module;
decreasing an amplification factor for generating the magnetic field detection signal;
decreasing an operational gain for generating the magnetic field detection signal.

4. The magnetic field detection apparatus according to claim 1, wherein comprising:
a first processing module having an output terminal coupled to an input terminal of the detection module, configured to output a first calibration value when the value of the reference signal satisfies the first relationship with the first preset value, and configured to output a second calibration value when the value of the reference signal satisfies the second relationship with the second preset value;
wherein the first calibration value is configured to increase a driving current or a driving voltage;
wherein the second calibration value is configured to decrease a driving current or a driving voltage.

5. The magnetic field detection apparatus according to claim 1, wherein comprising:
a first amplifier having an input terminal coupled to an output terminal of the detection module;
a first processing module having an output terminal coupled to a control terminal of the first amplifier, configured to output a third calibration value when the value of the reference signal satisfies the first relationship with the first preset value, and configured to output a fourth calibration value when the value of the reference signal satisfies the second relationship with the second preset value;
wherein the third calibration value is configured to increase an amplification factor;
wherein the fourth calibration value is configured to decrease an amplification factor.

6. The magnetic field detection apparatus according to claim 1, wherein comprising:
a second processing module having an input terminal coupled to an output terminal of the detection module, and having an output terminal configured to output a processed magnetic field detection signal;
a first processing module having an output terminal coupled to a control terminal of the second processing module, configured to output a fifth calibration value when the value of the reference signal satisfies the first relationship with a first preset value, and configured to output a sixth calibration value when the value of the reference signal satisfies the second relationship with a second preset value;
wherein the fifth calibration value is configured to increase an operational gain;
wherein the sixth calibration value is configured to decrease an operational gain.

7. The magnetic field detection apparatus according to claim 1, wherein the calibration module comprises:
a detection unit;
a magnetic field generator, configured to apply a calibration magnetic field to the detection unit; wherein a direction of the calibration magnetic field is parallel to a detection direction of the detection unit;
wherein the strength of the calibration magnetic field is characterized by a value of the reference signal.

8. The magnetic field detection apparatus according to claim 1, wherein the calibration module comprises:
a first magnetoresistor having a first terminal coupled to a power supply terminal;
a first magnetic field generator, configured to apply a first magnetic field to the first magnetoresistor;
a second magnetoresistor having a first terminal coupled to a second terminal of the first magnetoresistor, and having a second terminal coupled to a ground terminal;
a second magnetic field generator, configured to apply a second magnetic field to the second magnetoresistor, wherein the second magnetic field includes a magnetic field component opposite to a direction of the first magnetic field;
wherein the reference signal is related to a voltage value at the second terminal of the first magnetoresistor, or the reference signal is related to a voltage value at the first terminal of the second magnetoresistor;
wherein the first magnetoresistor has a positive magnetoresistance effect and the second magnetoresistor has a positive magnetoresistance effect, or
the first magnetoresistor has a negative magnetoresistance effect and the second magnetoresistor has a negative magnetoresistance effect.

9. The magnetic field detection apparatus according to claim 1, wherein the calibration module comprises:
a first magnetoresistor;
a first magnetic field generator, configured to apply a first magnetic field to the first magnetoresistor;
a second magnetoresistor having a preset position relationship with the first magnetoresistor and having a preset magnetoresistance effect relationship with the first magnetoresistor;
a second magnetic field generator, configured to apply a second magnetic field to the second magnetoresistor, wherein the second magnetic field includes a magnetic field component opposite to a direction of the first magnetic field;
wherein the preset position relationship satisfies one of the following:
a first terminal of the first magnetoresistor is coupled to a power supply terminal, and a first terminal of the second magnetoresistor is coupled to the power supply terminal;
a second terminal of the first magnetoresistor is coupled to a ground terminal, and a second terminal of the second magnetoresistor is coupled to the ground terminal;
wherein the preset magnetoresistance effect relationship satisfies one of the following:
the first magnetoresistor has a positive magnetoresistance effect and the second magnetoresistor has a positive magnetoresistance effect;
the first magnetoresistor has a negative magnetoresistance effect and the second magnetoresistor has a negative magnetoresistance effect.

10. The magnetic field detection apparatus according to claim 9, wherein the calibration module further comprises:
a third magnetoresistor having a first terminal coupled to the second terminal of the first magnetoresistor, and having a second terminal coupled to a ground terminal;
a fourth magnetoresistor having a first terminal coupled to the second terminal of the second magnetoresistor, and having a second terminal coupled to the ground terminal, and having a preset magnetoresistance effect relationship with the first magnetoresistor, the second magnetoresistor and the third magnetoresistor;
wherein the first terminal of the first magnetoresistor is coupled to a power supply terminal, and the first terminal of the second magnetoresistor is coupled to the power supply terminal;
wherein the first magnetic field generator is configured to apply a third magnetic field to the third magnetoresistor, and the second magnetic field generator is configured to apply a fourth magnetic field to the fourth magnetoresistor, wherein the fourth magnetic field includes a magnetic field component opposite to a direction of the third magnetic field, and the third magnetic field includes a magnetic field component same as the first magnetic field;
wherein the reference signal satisfies at least one of the following:
related to a voltage value at the second terminal of the first magnetoresistor;
related to a voltage value at the second terminal of the second magnetoresistor;
related to a voltage value at the first terminal of the third magnetoresistor;
related to a voltage value at the first terminal of the fourth magnetoresistor;
wherein the preset magnetoresistance effect relationship satisfies one of the following:
the first magnetoresistor has a negative magnetoresistance effect, the second magnetoresistor has a negative magnetoresistance effect, the third magnetoresistor has a positive magnetoresistance effect and the fourth magnetoresistor has a positive magnetoresistance effect;
the first magnetoresistor has a positive magnetoresistance effect, the second magnetoresistor has a positive magnetoresistance effect, the third magnetoresistor has a negative magnetoresistance effect and the fourth magnetoresistor has a negative magnetoresistance effect.

11. The magnetic field detection apparatus according to claim 9, wherein the calibration module further comprises:
a third magnetoresistor having a first terminal coupled to the second terminal of the first magnetoresistor, and having a second terminal coupled to a ground terminal;
a fourth magnetoresistor having a first terminal coupled to the second terminal of the second magnetoresistor, and having a second terminal coupled to the ground terminal, and having a preset magnetoresistance effect relationship with the first magnetoresistor, the second magnetoresistor and the third magnetoresistor;
wherein the first terminal of the first magnetoresistor is coupled to a power supply terminal, and the first terminal of the second magnetoresistor is coupled to the power supply terminal;
wherein the first magnetic field generator is configured to apply a fourth magnetic field to the fourth magnetoresistor, and the second magnetic field generator is configured to apply a third magnetic field to the third magnetoresistor, wherein the third magnetic field includes a magnetic field component opposite to a direction of the fourth magnetic field, and the third magnetic field includes a magnetic field component opposite to a direction of the first magnetic field;
wherein the reference signal satisfies at least one of the following:
related to a voltage value at the second terminal of the first magnetoresistor;
related to a voltage value at the second terminal of the second magnetoresistor;
related to a voltage value at the first terminal of the third magnetoresistor;
related to a voltage value at the first terminal of the fourth magnetoresistor;
wherein the preset magnetoresistance effect relationship satisfies one of the following:
the first magnetoresistor has a positive magnetoresistance effect, the second magnetoresistor has a positive magnetoresistance effect, the third magnetoresistor has a positive magnetoresistance effect and the fourth magnetoresistor has a positive magnetoresistance effect;
the first magnetoresistor has a negative magnetoresistance effect, the second magnetoresistor has a negative magnetoresistance effect, the third magnetoresistor has a negative magnetoresistance effect and the fourth magnetoresistor has a negative magnetoresistance effect.

12. The magnetic field detection apparatus according to claim 9, wherein the calibration module further comprises:
a third magnetoresistor having a first terminal coupled to the second terminal of the first magnetoresistor, and having a second terminal coupled to a ground terminal;
a fourth magnetoresistor having a first terminal coupled to the second terminal of the second magnetoresistor, and having a second terminal coupled to a ground terminal;
a fifth magnetoresistor having a first terminal coupled to a power supply terminal;
a sixth magnetoresistor having a first terminal coupled to a power supply terminal;
a seventh magnetoresistor having a first terminal coupled to a second terminal of the fifth magnetoresistor, and having a second terminal coupled to a ground terminal;
an eighth magnetoresistor having a first terminal coupled to a second terminal of the sixth magnetoresistor, and having a second terminal coupled to a ground terminal, and having a preset magnetoresistance effect relationship with the first magnetoresistor, the second magnetoresistor, the third magnetoresistor, the fourth magnetoresistor, the fifth magnetoresistor, the sixth magnetoresistor, and the seventh magnetoresistor;
wherein the first terminal of the first magnetoresistor is coupled to a power supply terminal, and the first terminal of the second magnetoresistor is coupled to the power supply terminal;
wherein the first magnetic field generator is configured to apply a third magnetic field to the third magnetoresistor, and the second magnetic field generator is configured to apply a fourth magnetic field to the fourth magnetoresistor, wherein the fourth magnetic field includes a magnetic field component opposite to a direction of the third magnetic field, and the third magnetic field includes a magnetic field component same as the first magnetic field;
wherein the first magnetic field generator is configured to apply a fifth magnetic field to the fifth magnetoresistor, and the second magnetic field generator is configured to apply a sixth magnetic field to the sixth magnetoresistor, wherein the sixth magnetic field includes a magnetic field component opposite to a direction of the fifth magnetic field;
wherein the first magnetic field generator is configured to apply a seventh magnetic field to the seventh magnetoresistor, and the second magnetic field generator is configured to apply an eighth magnetic field to the eighth magnetoresistor, wherein the eighth magnetic field includes a magnetic field component opposite to a direction of the seventh magnetic field, and the seventh magnetic field includes a magnetic field component same as the fifth magnetic field;
wherein the reference signal satisfies at least one of the following:
related to a voltage value at the second terminal of the first magnetoresistor;
related to a voltage value at the second terminal of the second magnetoresistor;
related to a voltage value at the first terminal of the third magnetoresistor;
related to a voltage value at the first terminal of the fourth magnetoresistor;
related to a voltage value at the second terminal of the fifth magnetoresistor;
related to a voltage value at the second terminal of the sixth magnetoresistor;
related to a voltage value at the first terminal of the seventh magnetoresistor;
related to a voltage value at the first terminal of the eighth magnetoresistor;
wherein the preset magnetoresistance effect relationship satisfies one of the following:
the first magnetoresistor has a negative magnetoresistance effect, the second magnetoresistor has a negative magnetoresistance effect, the third magnetoresistor has a positive magnetoresistance effect, the fourth magnetoresistor has a positive magnetoresistance effect, the fifth magnetoresistor has a negative magnetoresistance effect, the sixth magnetoresistor has a negative magnetoresistance effect, the seventh magnetoresistor has a positive magnetoresistance effect and the eighth magnetoresistor has a positive magnetoresistance effect;
the first magnetoresistor has a positive magnetoresistance effect, the second magnetoresistor has a positive magnetoresistance effect, the third magnetoresistor has a negative magnetoresistance effect, the fourth magnetoresistor has a negative magnetoresistance effect, the fifth magnetoresistor has a positive magnetoresistance effect, the sixth magnetoresistor has a positive magnetoresistance effect, the seventh magnetoresistor has a negative magnetoresistance effect and the eighth magnetoresistor has a negative magnetoresistance effect.

13. The magnetic field detection apparatus according to claim 9, wherein the calibration module further comprises:
a third magnetoresistor having a first terminal coupled to the second terminal of the first magnetoresistor, and having a second terminal coupled to a ground terminal;
a fourth magnetoresistor having a first terminal coupled to the second terminal of the second magnetoresistor, and having a second terminal coupled to a ground terminal;
a fifth magnetoresistor having a first terminal coupled to a power supply terminal;
a sixth magnetoresistor having a first terminal coupled to a power supply terminal;
a seventh magnetoresistor having a first terminal coupled to a second terminal of the fifth magnetoresistor, and having a second terminal coupled to a ground terminal;
an eighth magnetoresistor having a first terminal coupled to a second terminal of the sixth magnetoresistor, and having a second terminal coupled to a ground terminal, and having a preset magnetoresistance effect relationship with the first magnetoresistor, the second magnetoresistor, the third magnetoresistor, the fourth magnetoresistor, the fifth magnetoresistor, the sixth magnetoresistor, and the seventh magnetoresistor;
wherein the first terminal of the first magnetoresistor is coupled to a power supply terminal, and the first terminal of the second magnetoresistor is coupled to the power supply terminal;
wherein the first magnetic field generator is configured to apply a third magnetic field to the third magnetoresistor, and the second magnetic field generator is configured to apply a fourth magnetic field to the fourth magnetoresistor, wherein the fourth magnetic field includes a magnetic field component opposite to a direction of the third magnetic field, and the third magnetic field includes a magnetic field component same as the first magnetic field;
wherein the first magnetic field generator is configured to apply a fifth magnetic field to the fifth magnetoresistor, and the second magnetic field generator is configured to apply a sixth magnetic field to the sixth magnetoresistor, wherein the sixth magnetic field includes a magnetic field component opposite to a direction of the fifth magnetic field;
wherein the first magnetic field generator is configured to apply a seventh magnetic field to the seventh magnetoresistor, and the second magnetic field generator is configured to apply an eighth magnetic field to the eighth magnetoresistor, wherein the eighth magnetic field includes a magnetic field component opposite to a direction of the seventh magnetic field, and the seventh magnetic field includes a magnetic field component same as the fifth magnetic field;
wherein the reference signal satisfies at least one of the following:
related to a voltage value at the second terminal of the first magnetoresistor;
related to a voltage value at the second terminal of the second magnetoresistor;
related to a voltage value at the first terminal of the third magnetoresistor;
related to a voltage value at the first terminal of the fourth magnetoresistor;
related to a voltage value at the second terminal of the fifth magnetoresistor;
related to a voltage value at the second terminal of the sixth magnetoresistor;
related to a voltage value at the first terminal of the seventh magnetoresistor;
related to a voltage value at the first terminal of the eighth magnetoresistor;
wherein the preset magnetoresistance effect relationship satisfies one of the following:
the first magnetoresistor has a negative magnetoresistance effect, the second magnetoresistor has a negative magnetoresistance effect, the third magnetoresistor has a positive magnetoresistance effect, the fourth magnetoresistor has a positive magnetoresistance effect, the fifth magnetoresistor has a positive magnetoresistance effect, the sixth magnetoresistor has a positive magnetoresistance effect, the seventh magnetoresistor has a negative magnetoresistance effect and the eighth magnetoresistor has a negative magnetoresistance effect;
the first magnetoresistor has a positive magnetoresistance effect, the second magnetoresistor has a positive magnetoresistance effect, the third magnetoresistor has a negative magnetoresistance effect, the fourth magnetoresistor has a negative magnetoresistance effect, the fifth magnetoresistor has a negative magnetoresistance effect, the sixth magnetoresistor has a negative magnetoresistance effect, the seventh magnetoresistor has a positive magnetoresistance effect and the eighth magnetoresistor has a positive magnetoresistance effect.

14. The magnetic field detection apparatus according to claim 9, wherein the calibration module further comprises:
a third magnetoresistor having a first terminal coupled to the second terminal of the second magnetoresistor, and having a second terminal coupled to a ground terminal;
a fourth magnetoresistor having a first terminal coupled to the second terminal of the first magnetoresistor, and having a second terminal coupled to a ground terminal;
a fifth magnetoresistor having a first terminal coupled to a power supply terminal;
a sixth magnetoresistor having a first terminal coupled to a power supply terminal;
a seventh magnetoresistor having a first terminal coupled to a second terminal of the sixth magnetoresistor, and having a second terminal coupled to a ground terminal;
an eighth magnetoresistor having a first terminal coupled to a second terminal of the fifth magnetoresistor, and having a second terminal coupled to a ground terminal, and having a preset magnetoresistance effect relationship with the first magnetoresistor, the second magnetoresistor, the third magnetoresistor, the fourth magnetoresistor, the fifth magnetoresistor, the sixth magnetoresistor, and the seventh magnetoresistor;
wherein the first terminal of the first magnetoresistor is coupled to a power supply terminal, and the first terminal of the second magnetoresistor is coupled to the power supply terminal;
wherein the first magnetic field generator is configured to apply a third magnetic field to the third magnetoresistor, and the second magnetic field generator is configured to apply a fourth magnetic field to the fourth magnetoresistor, wherein the fourth magnetic field includes a magnetic field component opposite to a direction of the third magnetic field, and the third magnetic field includes a magnetic field component same as the first magnetic field;
wherein the first magnetic field generator is configured to apply a fifth magnetic field to the fifth magnetoresistor, and the second magnetic field generator is configured to apply a sixth magnetic field to the sixth magnetoresistor, wherein the sixth magnetic field includes a magnetic field component opposite to a direction of the fifth magnetic field;
wherein the first magnetic field generator is configured to apply a seventh magnetic field to the seventh magnetoresistor, and the second magnetic field generator is configured to apply an eighth magnetic field to the eighth magnetoresistor, wherein the eighth magnetic field includes a magnetic field component opposite to a direction of the seventh magnetic field, and the seventh magnetic field includes a magnetic field component same as the fifth magnetic field;
wherein the reference signal satisfies at least one of the following:
related to a voltage value at the second terminal of the first magnetoresistor;
related to a voltage value at the second terminal of the second magnetoresistor;
related to a voltage value at the first terminal of the third magnetoresistor;
related to a voltage value at the first terminal of the fourth magnetoresistor;
related to a voltage value at the second terminal of the fifth magnetoresistor;
related to a voltage value at the second terminal of the sixth magnetoresistor;
related to a voltage value at the first terminal of the seventh magnetoresistor;
related to a voltage value at the first terminal of the eighth magnetoresistor;
wherein the preset magnetoresistance effect relationship satisfies one of the following:
the first magnetoresistor has a positive magnetoresistance effect, the second magnetoresistor has a positive magnetoresistance effect, the third magnetoresistor has a positive magnetoresistance effect, the fourth magnetoresistor has a positive magnetoresistance effect, the fifth magnetoresistor has a positive magnetoresistance effect, the sixth magnetoresistor has a positive magnetoresistance effect, the seventh magnetoresistor has a positive magnetoresistance effect and the eighth magnetoresistor has a positive magnetoresistance effect, or
the first magnetoresistor has a negative magnetoresistance effect, the second magnetoresistor has a negative magnetoresistance effect, the third magnetoresistor has a negative magnetoresistance effect, the fourth magnetoresistor has a negative magnetoresistance effect, the fifth magnetoresistor has a negative magnetoresistance effect, the sixth magnetoresistor has a negative magnetoresistance effect, the seventh magnetoresistor has a negative magnetoresistance effect and the eighth magnetoresistor has a negative magnetoresistance effect.

15. The magnetic field detection apparatus according to claim 1, wherein the calibration module comprises:
a first Hall element having a detection direction perpendicular to a mounting plane of the first Hall element, having a first terminal coupled to a power supply terminal, and having a second terminal coupled to a ground terminal;
a second Hall element having a detection direction perpendicular to a mounting plane of the second Hall element, having a first terminal coupled to a power supply terminal, having a second terminal coupled to a ground terminal, having a third terminal coupled to a fourth terminal of the first Hall element, and having a fourth terminal coupled to a third terminal of the first Hall element.

16. The magnetic field detection apparatus according to claim 1, wherein the detection module comprises:
a first detection module disposed in a first region;
a second detection module disposed in a second region different from the first region, having an output terminal coupled to an output terminal of the first detection module, and configured to generate the magnetic field detection signal.

17. The magnetic field detection apparatus according to claim 1, wherein the detection module comprises:
a first detection module disposed in a first region;
a second detection module disposed in a second region different from the first region;
wherein the magnetic field detection apparatus further comprises a first amplifier having a first input terminal coupled to an output terminal of the first detection module, and having a second input terminal coupled to an output terminal of the second detection module, wherein the first amplifier is configured to generate the magnetic field detection signal.

18. The magnetic field detection apparatus according to claim 1, wherein the detection module comprises:
a first detection module disposed in a first region, configured to generate a first detection signal;
a second detection module disposed in a second region different from the first region, configured to generate a second detection signal;
wherein the magnetic field detection apparatus further comprises a subtractor, configured to generate the magnetic field detection signal based on the first detection signal and the second detection signal.
